(19) United States
(12) Patent Application Publication
(10) Pub. No.: US 2026/0101779 A1
(43) Pub. Date: Apr. 9, 2026

(54) ELECTRONIC MODULE AND ELECTRONIC EQUIPMENT

(71) Applicant: CANON KABUSHIKI KAISHA, Tokyo (JP)

(72) Inventors: TAKAYUKI TAGUCHI, Kanagawa (JP); HIROYUKI YAMAGUCHI, Kanagawa (JP)

(21) Appl. No.: 19/344,845

(22) Filed: Sep. 30, 2025

(30) Foreign Application Priority Data
Oct. 9, 2024 (JP) 2024-177314

(51) Int. Cl. H01L 23/538; H01L 23/00; H01L 23/552

(52) U.S. Cl. CPC H10W 70/611; H10W 42/20; H10W 70/65; H10W 90/401; H10W 90/754

(57) ABSTRACT

An electronic module includes a semiconductor element including an analog circuit and a digital circuit, and a wiring unit including a first power wiring for the analog circuit, a second power wiring for the digital circuit and a third power wiring for the digital circuit. The first power wiring includes first power wiring patterns. The second power wiring includes second power wiring patterns. A distance between a first wiring layer in which a first wiring pattern having a largest area among the first power wiring patterns is disposed and a second wiring layer in which a second wiring pattern having a largest area among the second power wiring patterns is disposed is 500 μm or more. The wiring unit includes a third wiring layer disposed between a first portion of the first wiring pattern and a second portion of the second wiring pattern.

### BACKGROUND

### Field of the Technology

The present disclosure relates to an electronic module and electronic equipment, the electronic module including a semiconductor element that includes an analog circuit and a digital circuit.

### Description of the Related Art

As a semiconductor element including an analog circuit and a digital circuit, JP 2015-126385 A discloses an imaging device including a pixel circuit, an analog signal processing circuit, and a digital signal processing circuit. In addition, JP 2015-126385 A discloses that power supply potentials DVDD, SVDD, and AVDD and reference potentials (ground potentials) DGND, SGND, and AGND are supplied from the outside.

When potential fluctuations of a power wiring connected to one of the analog circuit and the digital circuit affect a potential of a power wiring connected to the other of the analog circuit and the digital circuit, there is a possibility that an operation of the semiconductor element becomes unstable, for example, performance degradation or malfunction of the analog circuit and/or the digital circuit occurs.

### SUMMARY

The present disclosure provides an advantageous technology for stabilizing an operation of a semiconductor element.

According to a first aspect of the present disclosure, an electronic module includes a semiconductor element including an analog circuit and a digital circuit, and a wiring unit having a mounting surface on which the semiconductor element is mounted, and including a first power wiring used to supply power to the analog circuit, a second power wiring used to supply power to the digital circuit, and a third power wiring used to supply power to the digital circuit. The first power wiring includes two or more first power wiring patterns disposed in two or more wiring layers of the wiring unit. The second power wiring includes two or more second power wiring patterns disposed in two or more wiring layers of the wiring unit. The wiring unit includes a first wiring layer in which a first wiring pattern having a largest area among the two or more first power wiring patterns is disposed and a second wiring layer in which a second wiring pattern having a largest area among the two or more second power wiring patterns is disposed. A distance between the first wiring layer and the second wiring layer is 500 μm or more. At least a first portion of the first wiring pattern overlaps with at least a second portion of the second wiring pattern in a direction perpendicular to the mounting surface. The wiring unit includes a third wiring layer disposed between the first portion and the second portion in the direction perpendicular to the mounting surface.

According to a second aspect of the present disclosure, an electronic module includes a semiconductor element including an analog circuit and a digital circuit, and a wiring unit having a mounting surface on which the semiconductor element is mounted, and including a first power wiring used to supply power to the analog circuit and a second power wiring used to supply power to the digital circuit. The first power wiring includes two or more first power wiring patterns disposed in two or more wiring layers of the wiring unit. The second power wiring includes two or more second power wiring patterns disposed in two or more wiring layers of the wiring unit. A distance between a first wiring pattern having a largest area among the two or more first power wiring patterns and a second wiring pattern having a largest area among the two or more second power wiring patterns is 900 μm or more.

According to a third aspect of the present disclosure, an electronic module includes a semiconductor element including an analog circuit and a digital circuit, and a wiring unit having a mounting surface on which the semiconductor element is mounted, and including a first power wiring used to supply power to the analog circuit and a second power wiring used to supply power to the digital circuit. The first power wiring includes two or more first power wiring patterns disposed in two or more wiring layers of the wiring unit. The second power wiring includes two or more second power wiring patterns disposed in two or more wiring layers of the wiring unit. The wiring unit includes a first wiring board and a second wiring board stacked on each other. A first wiring pattern having a largest area among the two or more first power wiring patterns is provided in the first wiring board. A second wiring pattern having a largest area among the two or more second power wiring patterns is provided in the second wiring board.

Features of the present disclosure will become apparent from the following description of embodiments with reference to the attached drawings. The following description of embodiments is described by way of example.

### BRIEF DESCRIPTION OF THE DRAWINGS

FIG. 1 is an explanatory view of a digital camera which is an example of a system to which a module according to a first embodiment is applied.

FIG. 2A is an explanatory view of an imaging module according to the first embodiment.

FIG. 2B is an explanatory view of the imaging module according to the first embodiment.

FIG. 2C is an explanatory view of the imaging module according to the first embodiment.

FIG. 3 is a schematic cross-sectional view of the imaging module according to the first embodiment.

FIG. 4A is an explanatory view of a semiconductor element according to the first embodiment.

FIG. 4B is an explanatory view of a wiring configuration connected to a pixel according to the first embodiment.

FIG. 5 is a schematic perspective view of a connection member according to the first embodiment.

FIG. 6A is an explanatory view of a part of an analog power supply wiring according to the first embodiment.

FIG. 6B is an explanatory view of a part of a digital power supply wiring according to the first embodiment.

FIG. 7A is an explanatory view of one wiring layer of a first wiring board according to a first modified example.

FIG. 7B is a cross-sectional view of a part of an imaging module according to the first modified example.

FIG. 8 is a schematic cross-sectional view of an imaging module according to a second modified example.

FIG. 9A is a perspective view of two connection members of a wiring unit of an imaging module according to a second embodiment.

FIG. 9B is a perspective view of two connection members of a wiring unit of an imaging module according to a fourth modified example.

FIG. 10 is a schematic cross-sectional view of an imaging module according to a third embodiment.

FIG. 11A is a schematic cross-sectional view of an imaging module according to a fourth embodiment.

FIG. 11B is a schematic cross-sectional view of an imaging module of a first comparative example.

### DESCRIPTION OF THE EMBODIMENTS

Hereinafter, embodiments of the present disclosure will be described in detail with reference to the drawings. The embodiments described below are merely examples, and for example, detailed configurations can be appropriately changed and implemented by those skilled in the art without departing from the gist of the present disclosure.

In the drawings referred to in the following embodiments and description, elements denoted by the same reference signs have the same functions unless otherwise specified. In the drawings, in a case where a plurality of the same elements are arranged, reference signs and a description thereof may be omitted. In addition, the drawings may be schematic for convenience of illustration and description, and thus, the shape, size, arrangement, and the like of elements in the drawings may not strictly match those of elements in other drawings and those of actual ones.

In the following embodiments, directions are indicated by an XYZ coordinate system, which is an orthogonal coordinate system. An X axis, a Y axis, and a Z axis are orthogonal to one another. A direction of the X axis is also referred to as an X direction, a direction of the Y axis is also referred to as a Y direction, and a direction of the Z axis is also referred to as a Z direction. Further, for example, a +X-axis direction indicates the same direction as that indicated by an X-axis arrow in the illustrated coordinate system, and a −X-axis direction indicates a direction 180 degrees opposite to that indicated by the X-axis arrow in the illustrated coordinate system. In addition, a direction simply referred to as the X direction is a direction parallel to the X axis regardless of a difference from the direction indicated by the illustrated X-axis arrow. The same applies to the Y axis and the Z axis other than the X axis. For example, a plane including the X axis and the Y axis is expressed as an XY plane. The same applies to an XZ plane and a YZ plane.

### First Embodiment

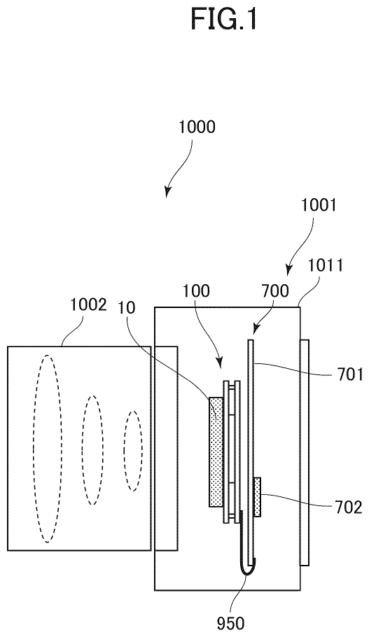

FIG. 1 is an explanatory view of a digital camera 1000 which is an example of a system to which an electronic module according to a first embodiment is applied. The digital camera 1000 is a digital camera with an interchangeable lens in this example, and includes a camera body 1001 that is electronic equipment. A lens unit 1002 including a lens is attachable to and detachable from the camera body 1001. The digital camera 1000 is not limited to the digital camera with an interchangeable lens, and may be a lens-integrated digital camera in which the camera body 1001 and the lens unit 1002 are integrated with each other. The camera body 1001 includes an exterior housing 1011, and an imaging module 100 and a processing module 700 that are disposed inside the exterior housing 1011. The imaging module 100 is an example of a first electronic module, and the processing module 700 is an example of a second electronic module. The imaging module 100 and the processing module 700 are electrically connected to each other via a wiring component 950. The wiring component 950 preferably has flexibility (bendability), and is, for example, a flexible printed wiring board or a flexible flat cable. A signal indicating image data generated in the imaging module 100 is transmitted to the processing module 700 via the wiring component 950.

The processing module 700 includes a printed wiring board 701 and an image processing device 702 mounted on the printed wiring board 701. The image processing device 702 is, for example, a digital signal processor. The image processing device 702 is a semiconductor element such as a semiconductor package, and is also an integrated circuit component. The image processing device 702 is configured to perform image processing on the image data acquired from the imaging module 100.

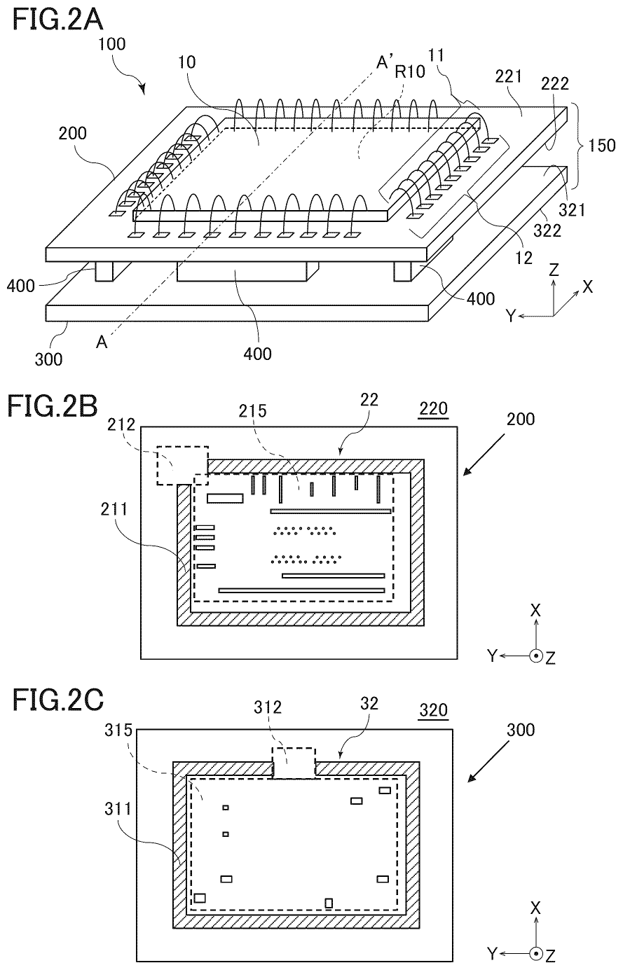

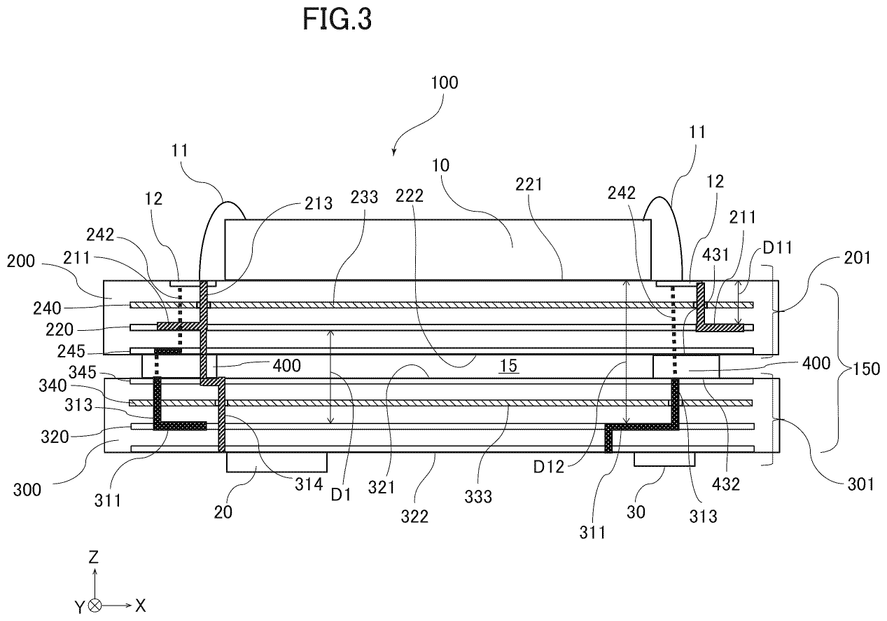

FIGS. 2A, 2B, and 2C are explanatory views of the imaging module 100 according to the first embodiment. FIG. 3 is a schematic cross-sectional view of the imaging module 100 according to the first embodiment. FIG. 3 illustrates a schematic cross section of the imaging module 100 along a virtual plane parallel to the XZ plane, including line A-A′ in FIG. 2A. A configuration of the imaging module 100 will be described.

FIG. 2A is a perspective view of the imaging module 100. The imaging module 100 is an example of the electronic module and has a three-dimensional mounting structure. The imaging module 100 includes a semiconductor element 10 that is an imaging element and a wiring unit 150 on which the semiconductor element 10 is mounted.

The wiring unit 150 includes a wiring board 200, a wiring board 300, and one or more connection members that connect between the wiring board 200 and the wiring board 300. In the first embodiment, the one or more connection members are a plurality of (for example, four) connection members 400. The connection member 400 is a wiring member. The semiconductor element 10 is also an integrated circuit component including a semiconductor chip. The semiconductor element 10 is mounted on the wiring board 200.

The wiring board 200 is a printed wiring board. The wiring board 200 is, for example, a rigid board. The wiring board 200 has two main surfaces 221 and 222. The semiconductor element 10 is mounted on the main surface 221 of the wiring board 200. That is, the main surface 221 is a mounting surface of the wiring unit 150 on which the semiconductor element 10 is mounted. The main surface 222 is a main surface opposite to the main surface 221. The main surface 222 is parallel to the main surface 221. The Z direction is a direction perpendicular to the main surface 221. The X direction and the Y direction are parallel to the main surface 221.

The wiring board 300 is a printed wiring board. The wiring board 300 is, for example, a rigid board. The wiring board 300 has two main surfaces 321 and 322. The main surface 321 is a main surface opposite to the main surface 322. The main surface 322 is parallel to the main surface 321. In the Z direction, at least a part of the wiring board 200 and at least a part of the wiring board 300 overlap each other. The wiring board 300 is disposed adjacent to the main surface 222 of the wiring board 200. The main surface 321 of the wiring board 300 faces the main surface 222 of the wiring board 200. As described above, the wiring board 200 is disposed between the semiconductor element 10 and the wiring board 300.

The wiring board 200 and the wiring board 300 are stacked on each other with the plurality of connection members 400 interposed therebetween. That is, the wiring unit 150 has a three-dimensional mounting structure in which the wiring board 200 and the wiring board 300 are stacked in the Z direction with the plurality of connection members 400 interposed therebetween.

Here, the Z direction is also a direction in which the imaging module 100 is viewed from above. In addition, viewing in the Z direction, that is, in plan view, includes viewing through in the Z direction. The expression “in the Z direction” can include “when viewed in the Z direction”.

The plurality of connection members 400 are disposed between the main surface 222 of the wiring board 200 and the main surface 321 of the wiring board 300. Therefore, a gap 15 is formed between the wiring board 200 and the wiring board 300. A circuit component (not illustrated) or the like may be disposed in the gap 15.

The connection member 400 is a plate-like member. The connection member 400 is a printed wiring board smaller than the wiring board 200 and the wiring board 300. The connection member 400 is, for example, a rectangular parallelepiped rigid board. The connection member 400 is disposed between the wiring board 200 and the wiring board 300, and is used for electrical connection and mechanical connection between the wiring board 200 and the wiring board 300. The connection member 400 also functions as a spacer between the wiring board 200 and the wiring board 300.

The semiconductor element 10 has a rectangular shape when viewed in the Z direction. A connection surface 431 on one end side of the connection member 400 in the Z direction is connected to the main surface 222 of the wiring board 200 that is opposite to the main surface 221 on which the semiconductor element 10 is mounted by a bonding member such as a solder (not illustrated). A connection surface 432 on the other end side of the connection member 400 in the Z direction is connected to the main surface 321 of the wiring board 300 by a bonding member such as a solder (not illustrated).

A plurality of pads 12 are provided along an outer periphery of the semiconductor element 10 on the main surface 221 of the wiring board 200 on which the semiconductor element 10 is mounted. That is, the plurality of pads 12 are arranged along four sides of the semiconductor element 10. The semiconductor element 10 is electrically connected to the plurality of pads 12 by a plurality of wires 11. Each of the plurality of wires 11 is a bonding wire serving as an aerial wiring. That is, the plurality of wires 11 are bonded to the semiconductor element 10 and the main surface 221. The semiconductor element 10 can include a chip and a package that is a container that houses the chip, and the chip may be wire-bonded to the package. In this case, leads and lands of the package can be soldered to the pads on the main surface 221.

Power is supplied to the semiconductor element 10 from a side of the wiring board 200 via a corresponding pad 12 among the plurality of pads 12 and a corresponding wire 11 among the plurality of wires 11. In addition, the semiconductor element 10 exchanges a signal with the side of the wiring board 200 via a corresponding pad 12 among the plurality of pads 12 and a corresponding wire 11 among the plurality of wires 11.

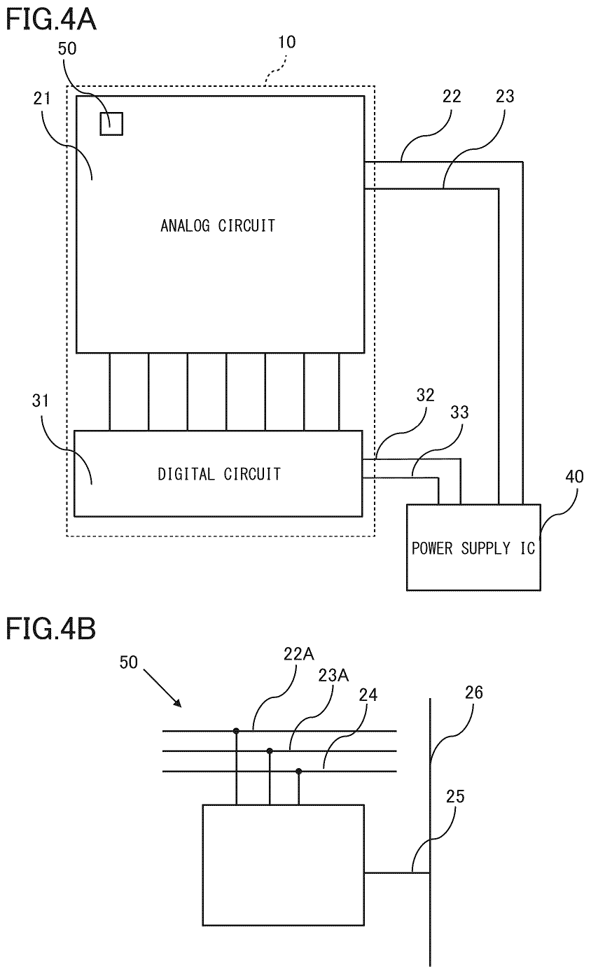

FIG. 4A is an explanatory view of the semiconductor element 10 according to the first embodiment. The semiconductor element 10 includes an analog circuit 21 and a digital circuit 31. The semiconductor element 10 is, for example, an imaging element configured to perform photoelectric conversion on a formed optical image. The semiconductor element 10 is an image sensor such as a complementary metal oxide semiconductor (CMOS) image sensor or a charge coupled device (CCD) image sensor.

The analog circuit 21 is a circuit that outputs a continuous charge or voltage change, and is a circuit in which a potential fluctuation of a power supply directly affects an output of a sensor or the like. The digital circuit 31 is a circuit other than the analog circuit 21, and is a circuit related to a digital signal or a logic circuit.

The semiconductor element 10 can be a stacked-type semiconductor element including two or more chips stacked on each other in the Z direction. The analog circuit 21 is included in one (first chip) of the two chips, and the digital circuit 31 is included in the other chip (second chip). By using the two chips, a scale of the digital circuit 31 can be increased. The present embodiment is suitable because the scale of the circuit tends to increase due to high functionality of the digital circuit, and an amount of a current flowing through the digital circuit tends to increase. It is a matter of course that the semiconductor element 10 is not limited to the stacked type, and may be a type in which the analog circuit 21 and the digital circuit 31 are integrated on a single semiconductor layer.

An analog power supply wiring 22 and a ground wiring 23 are connected to the analog circuit 21 of the semiconductor element 10 via internal wirings of the semiconductor element 10. The analog power supply wiring 22 and the ground wiring 23 are used to supply power to the analog circuit 21. Power necessary for circuit operation is supplied from a power supply IC 40 to the analog circuit 21 via the analog power supply wiring 22 and the ground wiring 23.

A digital power supply wiring 32 and a ground wiring 33 are connected to the digital circuit 31 of the semiconductor element 10 via internal wirings of the semiconductor element 10. The digital power supply wiring 32 and the ground wiring 33 are used to supply power to the digital circuit 31. Power necessary for circuit operation is supplied from the power supply IC 40 to the digital circuit 31 via the digital power supply wiring 32 and the ground wiring 33. That is, the analog power supply wiring 22 is used to supply power to the analog circuit 21, and the digital power supply wiring 32 is used to supply power to the digital circuit 31. The analog power supply wiring 22 is an example of a first power wiring. The digital power supply wiring 32 is an example of a second power wiring. The ground wiring 33 is an example of a third power wiring. The ground wiring 23 is an example of a fourth power wiring.

A power supply potential (first power supply potential) is supplied to the analog circuit 21 via the analog power supply wiring 22, and a reference potential is supplied to the analog circuit 21 via the ground wiring 23. The reference potential supplied to the analog circuit 21 is, for example, a ground potential.

Furthermore, a power supply potential (second power supply potential) is supplied to the digital circuit 31 via the digital power supply wiring 32, and a reference potential is supplied to the digital circuit 31 via the ground wiring 33. The reference potential supplied to the digital circuit 31 is, for example, a ground potential. The potential of the analog power supply wiring 22 is different from the potential of the ground wiring 33.

The power supply potential (the potential of the analog power supply wiring 22) supplied to the analog circuit 21 can be equal to or higher than the power supply potential (the potential of the digital power supply wiring 32) supplied to the digital circuit 31. For example, the potential of the analog power supply wiring 22 is 3.3 V, and the potential of the digital power supply wiring 32 is 1.8 V. Typically, the potential of the analog power supply wiring 22 and the potential of the digital power supply wiring 32 are different from each other, but may be the same as each other. The power supply potential and the reference potential transmitted by the wiring unit 150 may be supplied to the analog circuit 21 and the digital circuit 31 after the potentials are converted by a step-up circuit or a step-down circuit in the semiconductor element 10.

The reference potential (the potential of the ground wiring 23) supplied to the analog circuit 21 and the reference potential (the potential of the ground wiring 33) supplied to the digital circuit 31 may be different from each other or may be the same as each other.

Furthermore, the reference potential supplied to the analog circuit 21 and/or the reference potential supplied to the digital circuit 31 may be different from a ground potential of the entire camera. For example, in the analog circuit 21, the reference potential is a potential supplied to a photodiode of a pixel or a well of a transistor, and the reference potential may be a potential different from the ground potential of the entire camera, for example, a negative potential.

In addition, if the ground wiring 33 which is the third power wiring and the ground wiring 23 which is the fourth power wiring have the same potential, the ground wiring 33 and the ground wiring 23 may be implemented by one power wiring. That is, the third power wiring used to supply power to the digital circuit 31 may also be used to supply power to the analog circuit 21.

The analog power supply wiring 22 and the digital power supply wiring 32 are disposed in the wiring unit 150 illustrated in FIG. 2A. The analog power supply wiring 22 and the digital power supply wiring 32 are connected to the same power supply IC 40, but are not limited thereto, and may be connected to, for example, separate power supply ICs.

The analog circuit 21 of the semiconductor element 10 includes a plurality of pixels 50 arranged in a matrix. A wiring configuration connected to one pixel 50 among the plurality of pixels 50 will be described with reference to FIG. 4B. An analog power supply wiring 22A and a ground wiring 23A that are necessary for operation of the pixel 50, a signal wiring 24 for performing row reading and row selection, a reset wiring (not illustrated), and the like are connected to the pixel 50. The analog power supply wiring 22A, the ground wiring 23A, the signal wiring 24, and the reset wiring (not illustrated) are a part of the internal wirings of the semiconductor element 10. Light imaged on the pixel 50 is photoelectrically converted by the pixel 50, and an electric signal obtained by the photoelectric conversion is output to the outside of the analog circuit 21 via a row signal wiring 25 and a column signal wiring 26. The row signal wiring 25 and the column signal wiring 26 are a part of the internal wirings of the semiconductor element 10.

The digital circuit 31 of the semiconductor element 10 includes a horizontal scanning circuit, a vertical scanning circuit, a circuit related to data transfer, and the like. The digital circuit 31 outputs a digital signal to the pixel 50 via the signal wiring 24 that performs row reading and row selection, converts an electric signal output via the column signal wiring 26 into a digital signal, and transfers the digital signal to the image processing device 702 in FIG. 1.

As illustrated in FIG. 3, the semiconductor element 10 is mounted on the main surface 221 of the wiring board 200, and a circuit component 20 and a connector component 30 are mounted on the main surface 322 of the wiring board 300.

The wiring board 200 is a multilayer board including a plurality of wiring layers 201 arranged at intervals in the Z direction. In the example of FIG. 3, the number of wiring layers 201 is four. The plurality of wiring layers 201 are provided with a signal wiring (not illustrated) used for exchanging a signal with the semiconductor element 10, and a power supply wiring and a ground wiring used for supplying power to the semiconductor element 10. Conductors disposed in the plurality of wiring layers 201 are electrically connected by a via conductor (not illustrated) or the like.

The wiring board 300 is a multilayer board including a plurality of wiring layers 301 arranged at intervals in the Z direction. In the example of FIG. 3, the number of wiring layers 301 is four. The plurality of wiring layers 301 are provided with a signal wiring (not illustrated) used for exchanging a signal with the semiconductor element 10, and a power supply wiring and a ground wiring used for supplying power to the semiconductor element 10. Conductors disposed in the plurality of wiring layers 301 are electrically connected by a via conductor (not illustrated) or the like.

The four wiring layers 201 are disposed in the order of a first layer, a second layer, a third layer, and a fourth layer from the main surface 221 on which the semiconductor element 10 is mounted toward the main surface 222 in the −Z-axis direction. A wiring layer 220 illustrated in FIG. 2B is, for example, the third layer of the wiring board 200. The first layer of the wiring board 200 is mainly provided with the plurality of pads 12 and the signal wiring (not illustrated) connected to any of the plurality of pads 12. In a wiring layer 240 which is the second layer of the wiring board 200 positioned between the first layer and the third layer, a solid ground pattern 233 having a larger area than those of ground patterns of the ground wirings 23 of the other wiring layers is disposed in order to ensure potential stability of the first layer. A wiring to which the connection member 400 is connected is provided in a wiring layer 245 which is the fourth layer of the wiring board 200.

The four wiring layers 301 are disposed in the order of a first layer, a second layer, a third layer, and a fourth layer from the main surface 321 connected to the connection member 400 toward the main surface 322 in the −Z-axis direction. A wiring layer 320 illustrated in FIG. 2C is, for example, the third layer of the wiring board 300. A wiring layer 345 which is the first layer of the wiring board 300 is mainly provided with a wiring connected to the connection member 400. In a wiring layer 340 which is the second layer of the wiring board 300 positioned between the first layer and the third layer, a solid ground pattern 333 having a larger area than those of ground patterns of the ground wirings 33 of the other wiring layers is disposed. The circuit component 20 and the connector component 30 are mounted on the fourth layer of the wiring board 300, and the fourth layer of the wiring board 300 is mainly provided with a wiring connected to the circuit component 20 or the connector component 30. In a case where one power wiring is shared as the ground wiring 33 and the ground wiring 23, either the ground wiring 33 or the ground wiring 23 can be omitted. As the shared ground wiring is closer to a power supply wiring pattern of the analog power supply wiring 22 than to a power supply wiring pattern of the digital power supply wiring 32, noise in the analog circuit can be reduced. Therefore, the shared ground wiring can be disposed in any of the plurality of wiring layers 201 of the wiring board 200 that is the same as a power supply wiring pattern 211.

The plurality of connection members 400 are provided with a part of the signal wiring used for exchanging a signal between the wiring board 200 and the wiring board 300, a part of each of the analog power supply wiring 22 and the digital power supply wiring 32 used for power supply, and a part of each of the ground wirings 23 and 33.

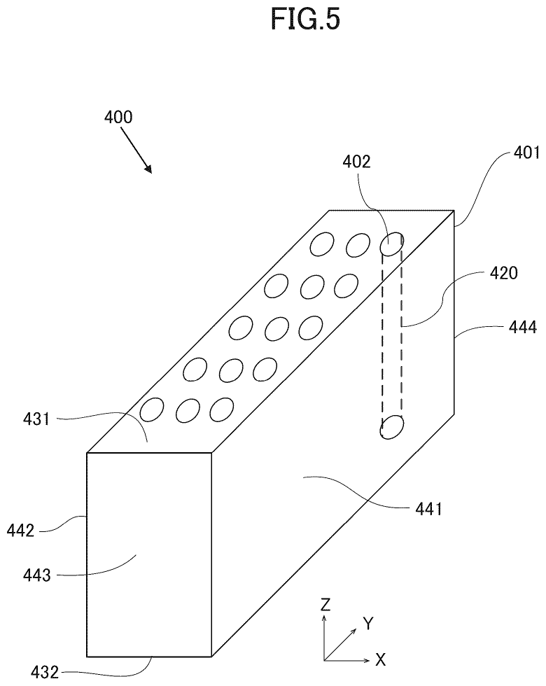

FIG. 5 is a schematic perspective view of the connection member 400 according to the first embodiment. FIG. 5 illustrates one of the four connection members 400, for example, the left connection member 400 illustrated in FIG. 3. In FIG. 5, a longitudinal direction of the connection member 400 is the Y direction, and a lateral direction of the connection member 400 is the X direction.

The connection member 400 includes a rectangular parallelepiped insulating substrate 401 and a plurality of via conductors 402 disposed in the insulating substrate 401. Each of the plurality of via conductors 402 is a conductor. A plurality of through-holes 420 are formed in the insulating substrate 401, and each of the plurality of via conductors 402 is a through-hole conductor disposed in a corresponding through-hole 420 among the plurality of through-holes 420.

The connection member 400 has a pair of connection surfaces 431 and 432 directed in the Z direction and four side surfaces 441 to 444 perpendicular to the connection surfaces 431 and 432. The connection surface 431 is connected to the wiring board 200 by the bonding member (not illustrated), and the connection surface 432 is connected to the wiring board 300 by the bonding member (not illustrated).

Each of the plurality of via conductors 402 is a part of any of the signal wiring, the power supply wiring, and the ground wiring. Each of the plurality of via conductors 402 is formed in the through-hole 420 extending in a straight line shape indicated by a broken line from the connection surface 431 connected to the wiring board 200 to the connection surface 432 connected to the wiring board 300. With such a configuration of the connection member 400, the connection member 400 can be further downsized. The connection member 400 is not limited to such a configuration, and may be implemented by a multilayer board in which a conductor is provided in an inner layer.

Although only one circuit component 20 is illustrated in FIG. 3, the number of circuit components 20 is not limited to one, and a plurality of circuit components 20 may be mounted on the wiring board 300. The plurality of circuit components 20 can include, for example, a resistor component, a capacitor component, a component forming a part of a power supply circuit, and a noise filter component. The wiring component 950 in FIG. 1 is connected to the connector component 30, and signal exchange between the processing module 700 and the imaging module 100 and power supply from the power supply IC 40 in FIG. 4A to the imaging module 100 are performed via the wiring component 950. The power supply IC 40 can also be mounted on the wiring unit 150, and at least one of the plurality of circuit components 20 may be the power supply IC 40.

Although only one connector component 30 is illustrated in FIG. 3, the number of connector components 30 is not limited to one, and a plurality of connector components 30 may be mounted on the wiring board 300. The plurality of connector components 30 can be used for various transmission applications such as the signal wiring (not illustrated) and/or the power supply wiring. The connector component 30 may be omitted, and the wiring component 950 may be directly bonded to the wiring unit 150 with a solder or an anisotropic conductive material.

Power is supplied to the imaging module 100 from the outside of the imaging module 100 via the wiring component 950 and the connector component 30. Then, power is supplied to the semiconductor element 10 via the analog power supply wiring 22 and the digital power supply wiring 32 of the wiring unit 150. As a result, a current flows through the analog power supply wiring 22 and the digital power supply wiring 32 according to operations of the analog circuit 21 and the digital circuit 31. For example, the power supply IC 40 mounted on an external board (not illustrated) includes a direct current (DC)/DC converter circuit that generates an arbitrary voltage, and power generated by the DC/DC converter circuit is supplied to the digital power supply wiring 32 via the wiring component 950 and the connector component 30. Similarly, power generated by the DC/DC converter circuit of the power supply IC 40 is supplied to the analog power supply wiring 22 via the wiring component 950 and the connector component 30, but an arbitrary voltage may be supplied to the analog power supply wiring 22 via a circuit such as a linear regulator included in the circuit component 20. By performing step-down processing by the linear regulator, a low noise voltage is generated, and the voltage is supplied to the analog power supply wiring 22.

Here, power is supplied from a circuit component mounted on the external board (not illustrated) to the analog power supply wiring 22 and the digital power supply wiring 32, but the present technology is not limited thereto. For example, power may be supplied from a power circuit mounted on the wiring board 300 to the analog power supply wiring 22 and the digital power supply wiring 32. In addition, it is sufficient if the supply of power to the analog power supply wiring and the potential fluctuation cause no issue in operation, and the supply of power may be performed without using the linear regulator.

The analog power supply wiring 22 connected to the analog circuit 21 of the semiconductor element 10 and the digital power supply wiring 32 connected to the digital circuit 31 of the semiconductor element 10 will be described.

The analog power supply wiring 22 includes two or more power supply wiring patterns disposed in two or more wiring layers included in the wiring unit 150. Each of two or more power supply wiring patterns of the analog power supply wiring 22 is an example of a first power wiring pattern. Two or more wiring layers in which two or more power supply wiring patterns of the analog power supply wiring 22 are disposed are included in the plurality of wiring layers 201 and the plurality of wiring layers 301. Among two or more power supply wiring patterns of the analog power supply wiring 22, a power supply wiring pattern having the largest area is the power supply wiring pattern 211 illustrated in FIG. 2B. The power supply wiring pattern 211 is an example of a first wiring pattern. The area of the power supply wiring pattern is an area in which a conductor layer such as a copper foil forming each wiring layer continuously extends. In a case where a plurality of power supply wiring patterns are disposed in one wiring layer, a wiring pattern having the largest area among the plurality of power supply wiring patterns can be the power supply wiring pattern having the largest area among two or more power supply wiring patterns of the analog power supply wiring 22. The area of the power supply wiring pattern 211 having the largest area can be, for example, 100 mm² or more, 200 mm² or more, 400 mm² or more, 500 mm² or more, 2000 mm² or less, or 1000 mm² or less. The power supply wiring pattern of the analog power supply wiring 22 other than the power supply wiring pattern 211 may be further disposed in the first wiring layer in which the power supply wiring pattern 211 having the largest area is disposed. That is, the plurality of power supply wiring patterns of the analog power supply wiring 22 may be disposed in the first wiring layer in which the power supply wiring pattern 211 having the largest area is disposed, and the power supply wiring pattern 211 is included in the plurality of power supply wiring patterns of the analog power supply wiring 22 in the first wiring layer. The sum of the areas of the power supply wiring patterns of the analog power supply wiring 22 disposed in each wiring layer can be maximized in the first wiring layer in which the power supply wiring pattern 211 having the largest area is disposed.

The digital power supply wiring 32 includes two or more power supply wiring patterns disposed in two or more wiring layers included in the wiring unit 150. Each of two or more power supply wiring patterns of the digital power supply wiring 32 is an example of a second power supply wiring pattern. Two or more wiring layers in which two or more power supply wiring patterns of the digital power supply wiring 32 are disposed are included in the plurality of wiring layers 201 and the plurality of wiring layers 301. Among two or more power supply wiring patterns of the digital power supply wiring 32, a power supply wiring pattern having the largest area is a power supply wiring pattern 311 illustrated in FIG. 2C. The power supply wiring pattern 311 is an example of a second wiring pattern. The area of the power supply wiring pattern is an area in which a conductor layer such as a copper foil forming each wiring layer continuously extends. In a case where a plurality of power supply wiring patterns are disposed in one wiring layer, a wiring pattern having the largest area among the plurality of power supply wiring patterns can be the power supply wiring pattern having the largest area among two or more power supply wiring patterns of the digital power supply wiring 32. The area of the power supply wiring pattern 311 having the largest area can be, for example, 100 mm² or more, 200 mm² or more, 400 mm² or more, 500 mm² or more, 2000 mm² or less, or 1000 mm² or less. The power supply wiring pattern of the digital power supply wiring 32 other than power supply wiring pattern 311 may be further disposed in the second wiring layer in which the power supply wiring pattern 311 having the largest area is disposed. That is, the plurality of power supply wiring patterns of the digital power supply wiring 32 may be disposed in the second wiring layer in which the power supply wiring pattern 311 having the largest area is disposed, and the power supply wiring pattern 311 is included in the plurality of power supply wiring patterns of the digital power supply wiring 32 in the second wiring layer. The sum of the areas of the power supply wiring patterns of the digital power supply wiring 32 disposed in each wiring layer can be maximized in the second wiring layer in which the power supply wiring pattern 311 having the largest area is disposed.

The ground wiring 33 includes two or more ground patterns disposed in two or more wiring layers included in the wiring unit 150. Each of two or more power supply wiring patterns of the ground wiring 33 is an example of a third power wiring pattern. Two or more wiring layers in which two or more ground patterns of the ground wiring 33 are disposed are included in the plurality of wiring layers 201 and the plurality of wiring layers 301. Among two or more ground patterns of the ground wiring 33, a ground pattern having the largest area is the ground pattern 333 illustrated in FIG. 3. The ground pattern 333 is an example of a third wiring pattern. The area of the ground pattern is an area in which a conductor layer such as a copper foil forming each wiring layer continuously extends. In a case where a plurality of ground patterns are disposed in one wiring layer, a wiring pattern having the largest area among the plurality of ground patterns can be the ground pattern having the largest area among two or more ground patterns of the ground wiring 33. The area of the ground pattern 333 having the largest area can be, for example, 100 mm² or more, 200 mm² or more, 400 mm² or more, 500 mm² or more, 2000 mm² or less, or 1000 mm² or less. The ground pattern of the ground wiring 33 other than the ground pattern 333 may be further disposed in the third wiring layer in which the ground pattern 333 having the largest area is disposed. That is, the plurality of ground patterns of the ground wiring 33 may be disposed in the third wiring layer in which the ground pattern 333 having the largest area is disposed, and the ground pattern 333 is included in the plurality of ground patterns of the ground wiring 33 in the third wiring layer. The sum of the areas of the ground patterns of the ground wiring 33 disposed in each wiring layer can be maximized in the third wiring layer in which the ground pattern 333 having the largest area is disposed.

The ground wiring 23 includes two or more ground patterns disposed in two or more wiring layers included in the wiring unit 150. Each of two or more ground patterns of the ground wiring 23 is an example of a fourth power wiring pattern. Two or more wiring layers in which two or more ground patterns of the ground wiring 23 are disposed are included in the plurality of wiring layers 201 and the plurality of wiring layers 301. Among two or more ground patterns of the ground wiring 23, a ground pattern having the largest area is the ground pattern 233 illustrated in FIG. 3. The ground pattern 233 is an example of a fourth wiring pattern. The area of the ground pattern is an area in which a conductor layer such as a copper foil forming each wiring layer continuously extends. In a case where a plurality of ground patterns are disposed in one wiring layer, a wiring pattern having the largest area among the plurality of ground patterns can be the ground pattern having the largest area among two or more ground patterns of the ground wiring 23. The area of the ground pattern 233 having the largest area can be, for example, 100 mm² or more, 200 mm² or more, 400 mm² or more, 500 mm² or more, 2000 mm² or less, or 1000 mm² or less. The ground pattern of the ground wiring 23 other than the ground pattern 233 may be further disposed in the fourth wiring layer in which the ground pattern 233 having the largest area is disposed. That is, the plurality of ground patterns of the ground wiring 23 may be disposed in the fourth wiring layer in which the ground pattern 233 having the largest area is disposed, and the ground pattern 233 is included in the plurality of ground patterns of the ground wiring 23 in the fourth wiring layer. The sum of the areas of the ground patterns of the ground wiring 23 disposed in each wiring layer can be maximized in the fourth wiring layer in which the ground pattern 233 having the largest area is disposed.

As described above, the analog circuit 21 is a circuit used to output a continuous charge or voltage change, and the potential fluctuation of the analog power supply wiring 22 directly affects the output of the analog circuit 21. For example, when the potential fluctuation of the analog power supply wiring 22 that supplies power to the pixel 50 of the analog circuit 21 is large, there is a possibility that disturbance occurs in an image generated by the semiconductor element 10 serving as the imaging element. On the other hand, the digital circuit 31 is a circuit related to a digital signal or a logic circuit, and the amount of the current flowing through the digital circuit 31 increases or an amount of noise occurring in the digital circuit 31 increases due to improvement in processing capability, which results from high functionality of the digital circuit 31. For example, the amount of the current supplied to the digital circuit 31 increases with improvement in functionality such as an increase in the number of pixels or an increase in signal transfer speed. As the amount of the current supplied to the digital circuit 31 increases, an amount of a current flowing through the digital power supply wiring 32 increases. Since a large amount of current flows through the digital power supply wiring 32, electromagnetic field noise radiated from the digital power supply wiring 32 tends to increase.

In the analog power supply wiring 22, the power supply wiring pattern having the largest area in one layer among the plurality of wiring layers 201 and the plurality of wiring layers 301 is the power supply wiring pattern 211. The power supply wiring pattern 211 is disposed in the wiring layer 220 among the plurality of wiring layers 201. The wiring layer 220 is an example of the first wiring layer. The power supply wiring pattern 211 is a wiring pattern that is most vulnerable to external noise in the analog power supply wiring 22. In the wiring layer 220, the power supply wiring pattern 211 is implemented by one or more wirings, and in the example of FIG. 2B, the power supply wiring pattern 211 is implemented by one wiring.

Further, in the digital power supply wiring 32, the power supply wiring pattern having the largest area in one layer among the plurality of wiring layers 201 and the plurality of wiring layers 301 is the power supply wiring pattern 311. The power supply wiring pattern 311 is disposed in the wiring layer 320 among the plurality of wiring layers 301. The wiring layer 320 is an example of the second wiring layer. The power supply wiring pattern 311 is a wiring pattern that generates the greatest radiated noise in the digital power supply wiring 32.

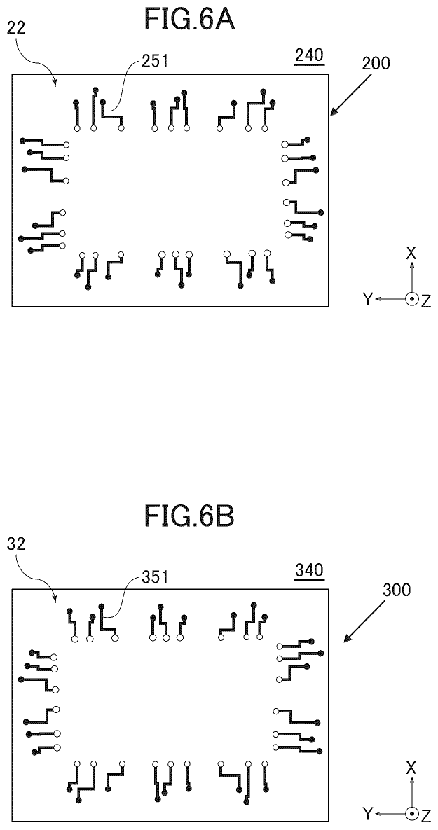

FIG. 6A is an explanatory view of a part of the analog power supply wiring 22 according to the first embodiment. Among two or more power supply wiring patterns of the analog power supply wiring 22, one or more power supply wiring patterns whose areas are smaller than that of the power supply wiring pattern 211, for example, a plurality of power supply wiring patterns 251 in the example of FIG. 6A, are disposed in a wiring layer other than the wiring layer 220 among the plurality of wiring layers 201 and the plurality of wiring layers 301, for example, the wiring layer 240 which is the second layer of the wiring board 200. Illustration of the wiring patterns (for example, the ground pattern 233) other than the power supply wiring pattern 251 in the wiring layer 240 is omitted.

FIG. 6B is an explanatory view of a part of the digital power supply wiring 32 according to the first embodiment. Among two or more power supply wiring patterns of the digital power supply wiring 32, one or more power supply wiring patterns whose areas are smaller than that of the power supply wiring pattern 311, for example, a plurality of power supply wiring patterns 351 in the example of FIG. 6B, are disposed in a wiring layer other than wiring layer 320 among the plurality of wiring layers 201 and the plurality of wiring layers 301, for example, the wiring layer 340 which is the second layer of the wiring board 300. Illustration of the wiring patterns (for example, the ground pattern 333) other than the power supply wiring pattern 351 in the wiring layer 340 is omitted.

When the electromagnetic field noise radiated from the power supply wiring pattern 311 reaches the power supply wiring pattern 211, the electromagnetic field noise propagates through the analog power supply wiring 22 and reaches the analog circuit 21 of the semiconductor element 10.

Therefore, in the first embodiment, the power supply wiring pattern 211 is provided in the wiring board 200 and the power supply wiring pattern 311 is provided in the wiring board 300 so as to keep the power supply wiring pattern 211 and the power supply wiring pattern 311 away from each other. That is, the wiring layer 220 is included in the plurality of wiring layers 201 of the wiring board 200, and the wiring layer 320 is included in the plurality of wiring layers 301 of the wiring board 300.

As described above, the power supply wiring pattern 211 and the power supply wiring pattern 311 are disposed in the wiring boards 200 and 300 different from each other, and thus, propagation of noise between the power supply wirings 22 and 32 is reduced, the potential fluctuation of the analog power supply wiring 22 is reduced, and the operation of the analog circuit 21 is stabilized. That is, the occurrence of disturbance such as streaks in the image generated by the plurality of pixels 50 is reduced.

Since the wiring board 200 and the wiring board 300 are connected via the connection member 400, the connection member 400 can keep the wiring board 200 and the wiring board 300 away from each other, and the power supply wiring pattern 211 and the power supply wiring pattern 311 can be kept away from each other.

A distance D12 between the main surface 221 of the wiring board 200 on which the semiconductor element 10 is mounted and the wiring layer 320 in which the power supply wiring pattern 311 is disposed is longer than a distance D11 between the main surface 221 of the wiring board 200 on which the semiconductor element 10 is mounted and the wiring layer 220 on which the power supply wiring pattern 211 is disposed. That is, the power supply wiring pattern 311 is disposed farther from the semiconductor element 10 than the power supply wiring pattern 211. As described above, the power supply wiring pattern 311 from which noise is radiated can be kept away from the semiconductor element 10.

The power supply wiring pattern 211 can be provided in the wiring board 200, and the power supply wiring pattern 311 can be provided in the wiring board 300, but the present technology is not limited thereto. For example, the power supply wiring pattern 211 may be provided in the wiring board 300, and the power supply wiring pattern 311 may be provided in the wiring board 200. In this case, the wiring board 300 is a first wiring board, and the wiring board 200 is a second wiring board.

The wiring unit 150 includes the wiring board 200 and the wiring board 300 connected by the connection member 400. The gap 15 is formed between the wiring board 200 and the wiring board 300 by the connection member 400. That is, the plurality of wiring layers 201 of the wiring board 200 and the plurality of wiring layers 301 of the wiring board 300 are disposed with the gap 15 interposed therebetween. Since the wiring layer 220 is included in the plurality of wiring layers 201, and the wiring layer 320 is included in the plurality of wiring layers 301, the gap 15 exists between the wiring layer 220 and the wiring layer 320 in addition to an insulating substrate of the wiring board 200 and an insulating substrate of the wiring board 300.

The insulating substrates of the wiring board 200 and wiring board 300 have a dielectric constant higher than that of air. For example, in a case where the insulating substrate is made of FR-4, a relative permittivity of the insulating substrate is about 4. Since the relative permittivity of air is 1, when the gap 15 is provided, a dielectric constant between the wiring layer 220 and the wiring layer 320 is lower than that in a case where only the insulating substrates are provided. Since the dielectric constant between the wiring layer 220 and the wiring layer 320 is low, noise propagating from the power supply wiring pattern 311 of the wiring layer 320 to the power supply wiring pattern 211 of the wiring layer 220 can be further reduced.

As illustrated in FIGS. 2A and 3, the plurality of pads 12 are disposed on the main surface 221. The plurality of pads 12 are used for supplying power to the semiconductor element 10 and exchanging a signal. The main surface 221 has a region R10 where the semiconductor element 10 is mounted. An outer shape of the region R10 corresponds to an outer shape of the semiconductor element 10 when viewed in the Z direction. The plurality of pads 12 are arranged at intervals along an outer periphery of the region R10. The analog power supply wiring 22 includes two or more pads 12 among the plurality of pads 12, and the digital power supply wiring 32 includes two or more pads 12 among the plurality of pads 12.

Here, the analog power supply wiring 22A and the ground wiring 23A, which are the internal wirings of the semiconductor element 10, are connected to each of the plurality of pixels 50 arranged in a matrix. At least two pads 12 of the analog power supply wiring 22 are dispersedly arranged along the outer periphery of the region R10 so as not to be biased. For example, at least two pads 12 of the analog power supply wiring 22 are uniformly arranged so as to surround the region R10. The semiconductor element 10 is disposed between at least two of the plurality of wires 11, and at least two wires 11 electrically connect the analog power supply wiring 22 and the semiconductor element 10 to each other. As a result, it is possible to reduce a difference in length between a plurality of analog power supply wirings 22A, which are the internal wirings of the semiconductor element 10, and it is possible to reduce a variation in supplied power (power supply voltage) for each pixel 50 of the semiconductor element 10. Also for the digital power supply wiring 32, at least two pads 12 of the digital power supply wiring 32 are dispersedly arranged along the outer periphery of the region R10 so as not to be biased.

In the Z direction, the power supply wiring pattern 211 is disposed so as to overlap with two or more pads 12 included in the analog power supply wiring 22. In the Z direction, the power supply wiring pattern 311 is disposed so as to overlap with two or more pads 12 included in the digital power supply wiring 32. Therefore, when viewed in the Z direction, the power supply wiring pattern 211 and the power supply wiring pattern 311 are formed to be long along the outer shape of the semiconductor element 10.

The power supply wiring pattern 211 and the power supply wiring pattern 311 are disposed so as to overlap with the pads 12 in the Z direction. However, the present technology is not limited thereto. For example, if there is no issue in increasing the areas of the wiring board 200 and the wiring board 300 on the XY plane, the power supply wiring pattern 211 and the power supply wiring pattern 311 may be provided on an outer side of the pads 12 when viewed from the region R10 in the Z direction.

In some embodiments, at least a part of each of the power supply wiring pattern 211 and the power supply wiring pattern 311 does not overlap with the semiconductor element 10 in the Z direction. In the first embodiment, the power supply wiring pattern 211 and the power supply wiring pattern 311 do not fully overlap with the semiconductor element 10 in the Z direction. With such a configuration, noise propagating from the power supply wiring pattern 211 and the power supply wiring pattern 311 to the semiconductor element 10 can be effectively reduced.

In some embodiments, at least a part (first portion) of the power supply wiring pattern 211 overlaps with at least a part (second portion) of the power supply wiring pattern 311 in the Z direction. Accordingly, the wiring boards 200 and 300 can be downsized. In a configuration in which at least a part of the power supply wiring pattern 211 and at least a part of the power supply wiring pattern 311 overlap with each other in the Z direction, the power supply wiring pattern 211 and the power supply wiring pattern 311 can be respectively disposed on the wiring boards 200 and 300 different from each other from the viewpoint of reducing electromagnetic coupling.

In addition, the power supply wiring pattern 211 may be disposed along the plurality of pads 12 and formed in an O shape when viewed in the Z direction. In the first embodiment, the power supply wiring pattern 211 can be formed in a C shape having a cut 212. In addition, the power supply wiring pattern 311 may be disposed along the plurality of pads 12 and formed in an O shape when viewed in the Z direction. In the first embodiment, the power supply wiring pattern 311 can be formed in a C shape having a cut 312. In this manner, formation of a closed loop in the power supply wiring patterns 211 and 311 is avoided. Therefore, even if magnetic field noise is coupled with regions 215 and 315 inside the power supply wiring patterns 211 and 311, generation of an induced electromotive force is reduced, and the occurrence of the potential fluctuation is reduced in the power supply wiring patterns 211 and 311.

In the region 215 indicated by a broken line inside the power supply wiring pattern 211, other power supply wirings, the signal wiring, a via land connected to a via conductor, and the like are provided. In addition, in the region 315 indicated by a broken line inside the power supply wiring pattern 311, other power supply wirings, the signal wiring, a via land connected to a via conductor, and the like are provided. Furthermore, in each of the region 215 and the region 315, a region other than a region where other power supply wirings, the signal wiring, and the via land are disposed is filled with the ground wiring. The cuts 212 and 312 are formed so as not to overlap with each other in the Z direction.

The power supply wiring pattern 211 is connected to the pad 12 via a via conductor 314 of the wiring board 300, the connection member 400, a via conductor 213 of the wiring board 200, and the like. In addition, the power supply wiring pattern 311 is connected to the pad 12 via a via conductor 313 of the wiring board 300, the connection member 400, a via conductor 242 of the wiring board 200, and the like. The power supply wiring pattern 311 includes two or more via conductors 242 disposed independently of each other in the wiring board 200. The two or more via conductors 242 are electrically connected outside the wiring board 200. The two or more via conductors 242 disposed independently of each other in the wiring board 200 are connected to two or more pads 12 included in the digital power supply wiring 32 on a one-to-one basis.

In the present embodiment, the cuts 212 and 312 are provided, and thus, each of the power supply wiring pattern 211 and the power supply wiring pattern 311 is formed in a C shape. However, the present technology is not limited thereto. For example, in a case where an intensity of the magnetic field noise reaching the power supply wiring patterns 211 and 311 from the outside is low, each of the power supply wiring patterns 211 and 311 may have a closed-loop O shape (ring shape). In addition, the power supply wiring pattern 211 may be implemented by a plurality of wirings arranged so as to be spaced apart from each other along an outer periphery of the region 215, and the power supply wiring pattern 311 may be implemented by a plurality of wirings arranged so as to be spaced apart from each other along an outer periphery of the region 315.

In addition, FIG. 4A illustrates a case where the analog circuit 21 and the digital circuit 31 are connected to the individual ground wirings 23 and 33, respectively, the ground wiring 23 serves as a current return path of the analog power supply wiring 22, and the ground wiring 33 serves as a current return path of the digital power supply wiring 32, but the present technology is not limited thereto. Although not illustrated, the analog circuit 21 and the digital circuit 31 may be connected to a common ground wiring. In this case, in the plurality of wiring layers 201 and the plurality of wiring layers 301, a region having no power supply wiring or signal wiring is filled with the ground patterns. The ground patterns disposed in the plurality of wiring layers 201 are connected by the via conductor. Similarly, the ground patterns disposed in the plurality of wiring layers 301 are connected by the via conductor. The ground pattern of each of the wiring layers 201 and 301 can be made larger, so that the potential fluctuation due to noise of the common ground wiring can be reduced.

As described above, according to the first embodiment, the power supply wiring pattern 211 is provided in the wiring board 200, and the power supply wiring pattern 311 is provided in the wiring board 300. Accordingly, the electromagnetic field noise propagating from the power supply wiring pattern 311 to the power supply wiring pattern 211 can be reduced, so that malfunction of the semiconductor element 10 and occurrence of image disturbance due to the semiconductor element 10 serving as the imaging element can be reduced.

In addition, as illustrated in FIG. 3, a distance D1 between the wiring layer 220 in which the power supply wiring pattern 211 is disposed and the wiring layer 320 in which the power supply wiring pattern 311 is disposed in the Z direction is 500 μm or more in some embodiments, and is 900 μm or more in a more specific embodiment. The distance D1 is also a distance between the power supply wiring pattern 211 and the power supply wiring pattern 311. By increasing the distance D1 in this manner, the electromagnetic field noise propagating from the power supply wiring pattern 311 to the power supply wiring pattern 211 is effectively reduced, so that the malfunction of the semiconductor element 10 and the occurrence of image disturbance due to, for example, the semiconductor element 10 serving as the imaging element is effectively reduced.

The wiring layers 245, 345, and 340 are disposed between the wiring layer 220 in which the power supply wiring pattern 211 is disposed and the wiring layer 320 in which the power supply wiring pattern 311 is disposed. Each of the wiring layers 245, 345, and 340 is an example of the third wiring layer. Since other wiring layers 245, 345, and 340 are disposed between the wiring layer 220 and the wiring layer 320, a distance between the wiring layer 220 and the wiring layer 320 can be increased, and thus, the electromagnetic field noise propagating from the power supply wiring pattern 311 to the power supply wiring pattern 211 is effectively reduced, so that the malfunction of the semiconductor element 10 and the occurrence of image disturbance due to, for example, the semiconductor element 10 serving as the imaging element is effectively reduced.

Here, an interference between the analog power supply wiring 22 connected to the analog circuit 21 and the ground wiring 23 and between the digital power supply wiring 32 connected to the digital circuit 31 and the ground wiring 33 is small. Then, by disposing the analog power supply wiring 22 and the ground wiring 23 as close as possible, it is possible to reduce radiated noise and coupling loops. Therefore, in some embodiments, a distance between the ground pattern 233 and the power supply wiring pattern 211 is shorter than the distance between the power supply wiring pattern 211 and the power supply wiring pattern 311. In the first embodiment, the distance between the ground pattern 233 and the power supply wiring pattern 211 is a distance D2 between the wiring layer 240 in which the ground pattern 233 is disposed and the wiring layer 220 in which the power supply wiring pattern 211 is disposed in the Z direction. The distance between the power supply wiring pattern 211 and the power supply wiring pattern 311 is a distance between wiring layer 220 in which the power supply wiring pattern 211 is disposed and the wiring layer 320 in which the power supply wiring pattern 311 is disposed in the Z direction. That is, in some embodiments, the distance D2 is shorter than the distance D1.

### First Modified Example

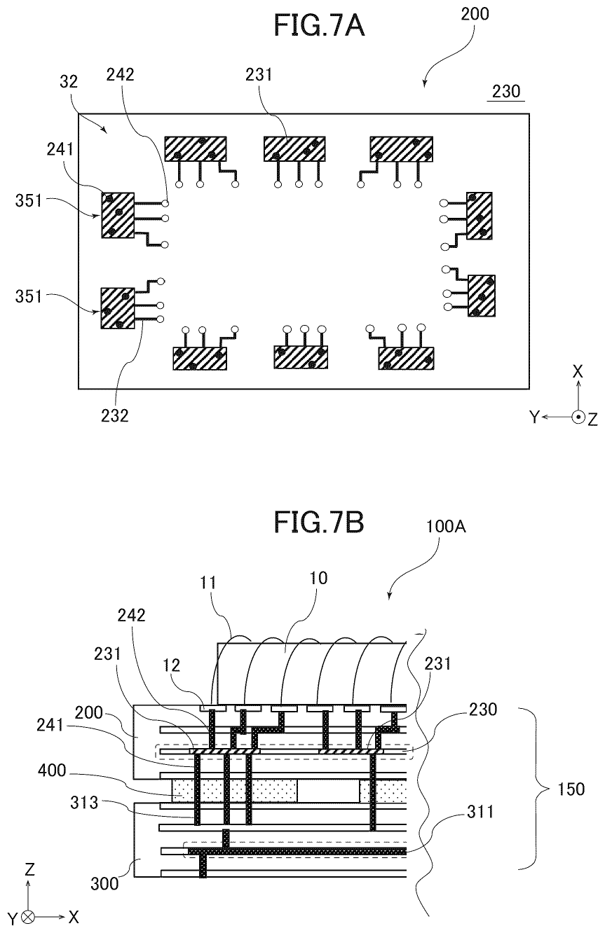

A first modified example is a modified example of the first embodiment. FIG. 7A is an explanatory view of a wiring layer 230 of a wiring board 200 according to the first modified example. FIG. 7B is a cross-sectional view of a part of an imaging module 100A according to the first modified example.

A digital power supply wiring 32 includes one or more power supply wiring patterns disposed in the wiring layer 230 different from a wiring layer 220 among a plurality of wiring layers 201 of the wiring board 200, such as a plurality of power supply wiring patterns 351 in the first modified example. Each of the plurality of power supply wiring patterns 351 includes a wiring 231 and two or more wirings 232. The wiring 231 is a planar conductor pattern.

Two or more (for example, three) via conductors 241 are connected to one of a plurality of wirings 231. In addition, one of the plurality of wirings 231 is connected to two or more (for example, three) via conductors 242 via two or more (for example, three) wirings 231. Two or more via conductors 242 are connected to two or more (for example, three) pads 12 of the digital power supply wiring 32, respectively. In this manner, two or more (for example, three) pads 12 may be collectively connected to one wiring 231 of the wiring layer 230. That is, among the plurality of pads 12, all the pads 12 included in the digital power supply wiring 32 may be divided into some groups and connected to the plurality of wirings 231 of the wiring layer 230. The same applies to the plurality of via conductors 241.

As described above, two or more via conductors 241 adjacent to each other among the plurality of via conductors 241 are collectively connected to one wiring 231 as one group. Then, two or more wirings 232 are led out from the wiring 231 according to the number of pads 12 connected to a semiconductor element 10, connected to two or more via conductors 242, and connected to two or more pads 12. Also in a case where an imaging module 100A has the above configuration, noise propagating from the digital power supply wiring 32 to an analog power supply wiring 22 can be reduced, so that operation of an analog circuit 21 is stabilized. Therefore, it is possible to reduce disturbance of an image generated by the semiconductor element 10 serving as an imaging element.

### Second Modified Example

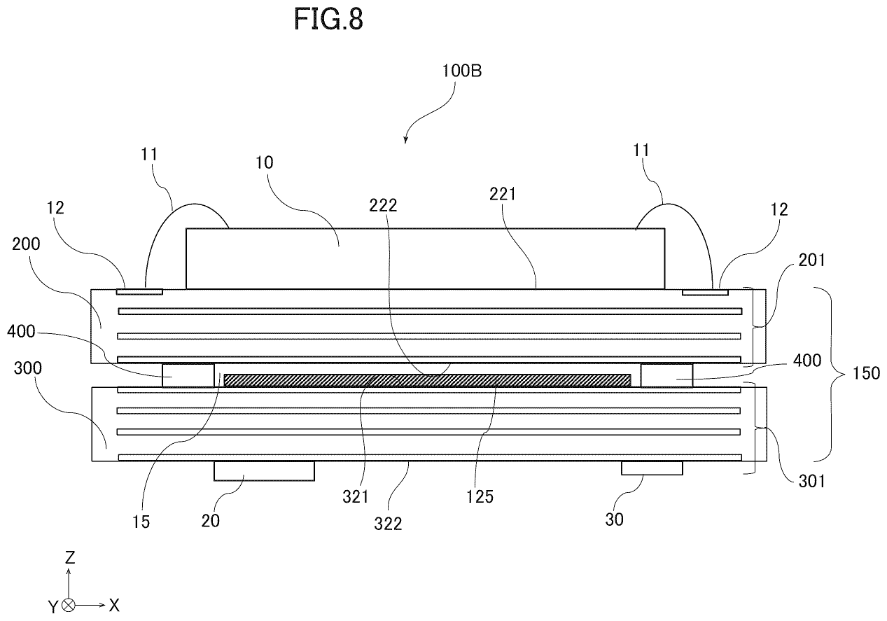

A second modified example is another modified example of the first embodiment. FIG. 8 is a schematic cross-sectional view of an imaging module 100B according to the second modified example. As illustrated in FIG. 8, a shield member 125 may be disposed in a gap 15. The shield member 125 can be a conductive member, that is, a metal member. Electromagnetic field noise propagating from a wiring layer 320 of a wiring board 300 to a wiring layer 220 of a wiring board 200 can be reduced by a shielding effect of the shield member 125.

The shield member 125 can be disposed on one of a main surface 222 of the wiring board 200 and a main surface 321 of the wiring board 300. Here, the shield member 125 can be connected to a ground wiring (ground potential) of the wiring board on which the shield member 125 is disposed, among the wiring board 200 and the wiring board 300. With such a configuration, a potential fluctuation of the shield member 125 is reduced, so that noise propagation can be further reduced. In the example of FIG. 8, the shield member 125 is disposed on the main surface 321 of the wiring board 300. Further, the shield member 125 is disposed between a plurality of connection members 400.

The shield member 125 can be disposed in the gap 15 so as to overlap with at least one of a power supply wiring pattern 211 and a power supply wiring pattern 311 in the Z direction. With such a configuration, electromagnetic field noise propagating from the power supply wiring pattern 311 to the power supply wiring pattern 211 can be more effectively reduced.

The shield member 125 can be connected to the ground potential, but is not limited thereto, and may be connected to, for example, a power supply potential or a floating potential.

### Third Modified Example

A third modified example is still another modified example of the first embodiment. In the first embodiment, the first modified example, and the second modified example, a case where the wiring unit 150 has a stacked structure in which the wiring board 200 and the wiring board 300 are stacked with the connection member 400 interposed therebetween has been described, but the present technology is not limited thereto. For example, the wiring board 200 and the wiring board 300 may be bonded by using a bonding member such as a solder instead of the connection member 400. However, it is advantageous to use the connection member 400 in that a distance between the wiring board 200 and the wiring board 300 can be increased as in the first embodiment, the first modified example, and the second modified example.

### Second Embodiment

Hereinafter, an imaging module according to a second embodiment will be described. Hereinafter, elements denoted by reference signs common to the first embodiment will have significantly the same configurations and actions as those described in the first embodiment unless otherwise specified, and portions different from those of the first embodiment will be mainly described.

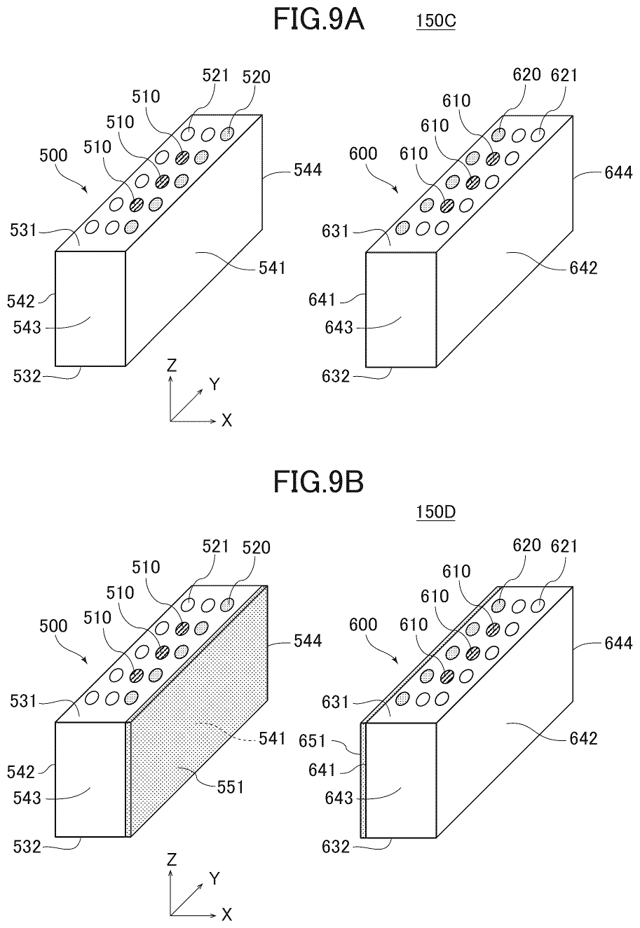

FIG. 9A is a perspective view of connection members 500 and 600 of a wiring unit 150C of the imaging module according to the second embodiment. In the wiring unit 150C illustrated in FIG. 9A, wiring boards 200 and 300 are not illustrated. Hereinafter, in the imaging module of the second embodiment, a description of the same configuration as that of the imaging module of the first embodiment will be omitted. In the second embodiment, two of the plurality of connection members 400 of the first embodiment are the connection members 500 and 600. The connection member 500 is an example of a first connection member, and the connection member 600 is an example of a second connection member. In FIG. 9A, a longitudinal direction of the connection members 500 and 600 is the Y direction, and a lateral direction of the connection members 500 and 600 is the X direction.

The connection member 500 has a pair of connection surfaces 531 and 532 directed to the Z direction and four side surfaces 541 to 544 perpendicular to the connection surfaces 531 and 532. The connection surface 531 is connected to the wiring board 200, and the connection surface 532 is connected to the wiring board 300.

The connection member 600 has a pair of connection surfaces 631 and 632 directed to the Z direction and four side surfaces 641 to 644 perpendicular to the connection surfaces 631 and 632. The connection surface 631 is connected to the wiring board 200, and the connection surface 632 is connected to the wiring board 300.

The connection member 500 and the connection member 600 are disposed at an interval in the X direction. One side surface 541 among four side surfaces 541 to 544 of the connection member 500 and one side surface 641 among four side surfaces 641 to 644 of the connection member 600 face each other in the X direction. The side surface 541 is an example of a first side surface, and the side surface 641 is an example of a second side surface.

An analog power supply wiring 22 is not disposed in the connection member 600, and a part of the analog power supply wiring 22 is disposed in the connection member 500. A digital power supply wiring 32 is not disposed in the connection member 500, and a part of the digital power supply wiring 32 is disposed in the connection member 600. As described above, the analog power supply wiring 22 and the digital power supply wiring 32 are wired to the different connection members 500 and 600, respectively.

The connection member 500 illustrated in FIG. 9A includes a power supply via conductor 510 forming a part of the analog power supply wiring 22 of FIG. 4A, and the connection member 600 includes a power supply via conductor 610 forming a part of the digital power supply wiring 32 of FIG. 4A. The connection member 500 includes a ground via conductor 520 which is an example of a first ground line. The connection member 600 includes a ground via conductor 620 which is an example of a second ground line. Specifically, the ground via conductor 520 is, for example, a part of a ground wiring 23 illustrated in FIG. 4A, and the ground via conductor 620 is, for example, a part of a ground wiring 33 illustrated in FIG. 4A.

In addition, the connection member 500 includes a signal via conductor 521 which is a part of a signal wiring (not illustrated), and the connection member 600 includes a signal via conductor 621 which is a part of a signal wiring (not illustrated). The power supply via conductor 510 of the analog power supply wiring 22 is disposed closer to a center side of the connection member 500 than the ground via conductor 520 and the signal via conductor 521 of the connection member 500. The power supply via conductor 610 of the digital power supply wiring 32 is disposed closer to a center side of the connection member 600 than the ground via conductor 620 and the signal via conductor 621 of the connection member 600.

The ground via conductor 520 is disposed between the side surface 541 of the connection member 500 and the power supply via conductor 510 in the X direction. Therefore, the ground via conductor 520 is disposed at a position between the power supply via conductor 510 and the power supply via conductor 610 in the X direction. With such a configuration, propagation of noise from the power supply via conductor 610 of the digital power supply wiring 32 to the power supply via conductor 510 of the analog power supply wiring 22 is reduced by the ground via conductor 520.

In addition, the ground via conductor 620 is disposed between the side surface 641 of the connection member 600 and the power supply via conductor 610 in the X direction. Therefore, the ground via conductor 620 is disposed at a position between the power supply via conductor 510 and the power supply via conductor 610 in the X direction. With such a configuration, noise propagation from the power supply via conductor 610 of the digital power supply wiring 32 to the power supply via conductor 510 of the analog power supply wiring 22 is reduced by the ground via conductor 620.

A gap is formed between the connection member 500 and the connection member 600. Therefore, propagation of noise from the connection member 600 to the connection member 500 is effectively reduced.

In addition, the power supply via conductor 510 is provided substantially at the center of the connection member 500, and the power supply via conductor 610 is provided substantially at the center of the connection member 600. That is, the power supply via conductor 510 is surrounded by the ground via conductor 520 and the signal via conductor 521. In addition, the power supply via conductor 610 is surrounded by the ground via conductor 620 and the signal via conductor 621. Therefore, by a shielding effect of the signal via conductor 521, the signal via conductor 621, the ground via conductor 520, and the ground via conductor 620, electromagnetic field noise leaking from the connection member 500 and the connection member 600 to the outside is reduced, and electromagnetic field noise entering the connection member 500 and the connection member 600 from the outside is blocked.

The ground via conductor 520 and the ground via conductor 620 are provided in the connection member 500 and the connection member 600, respectively, so as to be positioned between the power supply via conductor 510 and the power supply via conductor 610 in the X direction. Therefore, noise leaking from the power supply via conductor 610 and noise entering from the power supply via conductor 510 can be reduced by the shielding effect of the ground via conductor 520 and the ground via conductor 620 stable in terms of potential.

As described above, according to the second embodiment, the analog power supply wiring is connected to the connection member 500, and the digital power supply wiring is connected to the connection member 600 among the plurality of connection members 400. With such a configuration, electromagnetic field noise propagating from the connection member 500 to the connection member 600 can be reduced, so that malfunction of a semiconductor element 10 and occurrence of image disturbance due to, for example, the semiconductor element serving as an imaging element can be reduced.

An electronic component (not illustrated) or a metal member (not illustrated) may be disposed between the connection member 500 and the connection member 600. With such a configuration, noise leaking from the power supply via conductor 610 and noise entering from the power supply via conductor 510 can be reduced by a shielding effect of the electronic component (not illustrated) or the metal member (not illustrated).

### Fourth Modified Example

A fourth modified example is a modified example of the second embodiment. FIG. 9B is a perspective view of connection members 500 and 600 of a wiring unit 150D of an imaging module according to the fourth modified example. In the wiring unit 150D illustrated in FIG. 9B, wiring boards 200 and 300 are not illustrated.

An insulating substrate of each of the connection member 500 and the connection member 600 is an organic substrate having a substantially rectangular parallelepiped shape. A shield member can be disposed on at least one of a side surface 541 of the connection member 500 and a side surface 641 of the connection member 600. In the fourth modified example, a shield member 551 is disposed on the side surface 541, and a shield member 651 is disposed on the side surface 641. The shield members 551 and 651 are electrically connected to ground wirings (ground potentials) (not illustrated). The shield members 551 and 651 may be metal members or may be made of a conductive paint, a magnetic material, or the like. With such a configuration, noise propagating from a power supply via conductor 610 to a power supply via conductor 510 can be more effectively reduced.

In a case where a shield member is further disposed on any of side surfaces 542, 543, and 544 other than the side surface 541, the shield member 551 has a higher conductivity than that of the shield member in some embodiments. For example, the shield member 551 is thicker than the shield member. With such a configuration, noise propagating from the power supply via conductor 610 to the power supply via conductor 510 can be effectively reduced.

In addition, in a case where a shield member is further disposed on any of side surfaces 642, 643, and 644 other than the side surface 641, the shield member 651 has a conductivity higher than that of the shield member in some embodiments. For example, the shield member 651 is thicker than the shield member. With such a configuration, noise propagating from the power supply via conductor 610 to the power supply via conductor 510 can be effectively reduced. An electronic component or a metal member (not illustrated) may be disposed between the connection member 500 and the connection member 600.

In addition, the shield member 551 can be connected to the ground potential, but is not limited thereto, and may be connected to, for example, a power supply potential or a floating potential. Similarly, the shield member 651 can be connected to the ground potential, but is not limited thereto, and may be connected to, for example, a power supply potential or a floating potential.

### Third Embodiment

An imaging module according to a third embodiment will be described. Hereinafter, elements denoted by reference signs common to the first or second embodiment will have basically the same configurations and actions as those described in the first or second embodiment unless otherwise specified, and portions different from those of the first or second embodiment will be mainly described.

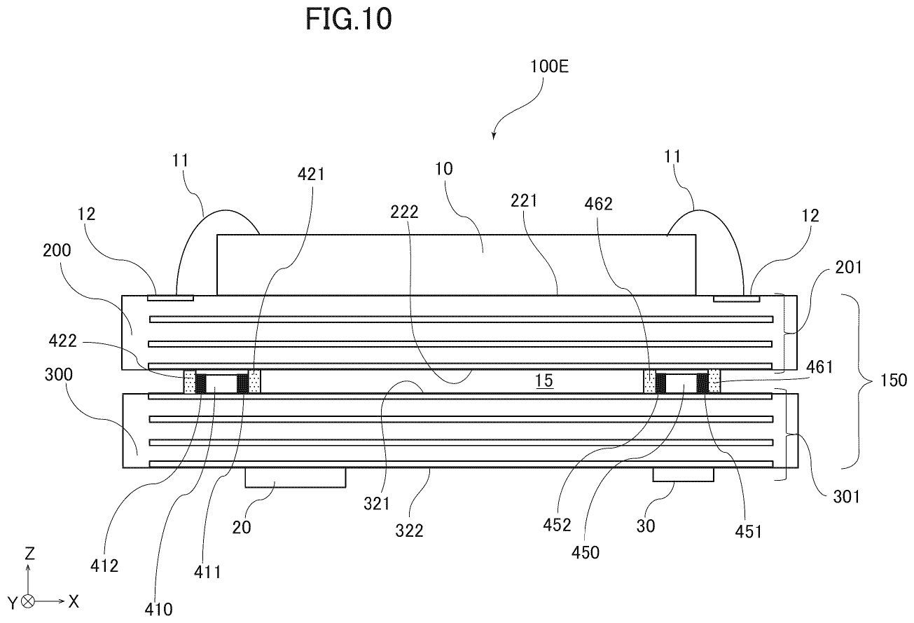

FIG. 10 is a schematic cross-sectional view of an imaging module 100E according to the third embodiment. In the third embodiment, instead of the plurality of connection members 400 of the first embodiment, one or more electronic components, for example, two electronic components 410 and 450, are disposed between a wiring board 200 and a wiring board 300. The electronic component 410 is an example of a first electronic component, and the electronic component 450 is an example of a second electronic component. The wiring board 200 and the wiring board 300 are connected via two electronic components 410 and 450.

The electronic component 410 includes terminals 411 and 412 and is bonded to the wiring boards 200 and 300 by bonding members 421 and 422 such as solders. The electronic component 450 includes terminals 451 and 452 and is bonded to the wiring boards 200 and 300 by bonding members 461 and 462 such as solders. The terminal 411 is an example of a first terminal, and the terminal 412 is an example of a second terminal. The terminal 451 is an example of a third terminal, and the terminal 452 is an example of a fourth terminal. The bonding member 421 is a part of an analog power supply wiring 22 in FIG. 4A. The bonding member 461 is a part of a digital power supply wiring 32 in FIG. 4A. The bonding members 422 and 462 are a part of ground wirings.

The electronic components 410 and 450 are passive components, and are, for example, capacitive elements. The electronic components 410 and 450 are chip components and are surface-mounted on a main surface 222 of the wiring board 200 and a main surface 321 of the wiring board 300. Accordingly, a distance between the wiring board 200 and the wiring board 300 in the Z direction is set to be equal to or larger than a thickness of each of the electronic components 410 and 450 in the Z direction.

The terminal 411 of the electronic component 410 is connected to the bonding member 421 of the analog power supply wiring 22. The terminal 451 of the electronic component 450 is connected to the bonding member 461 of the digital power supply wiring 32. The terminal 412 of the electronic component 410 is connected to the bonding member 422 of the ground wiring. The terminal 452 of the electronic component 450 is connected to the bonding member 462 of the ground wiring.

With the above configuration, power is supplied to an analog circuit 21 via the wiring board 300, the terminal 411 of the electronic component 410, and the wiring board 200, and power is supplied to a digital circuit 31 via the wiring board 300, the terminal 451 of the electronic component 450, and the wiring board 200. The terminal 412 of the electronic component 410 and the terminal 452 of the electronic component 450 are connected to the analog circuit 21 and the digital circuit 31 via the ground wirings of the wiring boards 200 and 300.

As described above, the wiring board 200 including a wiring layer 220 and the wiring board 300 including a wiring layer 320 are stacked via the electronic component 410 and the electronic component 450 instead of the connection member 400. Therefore, the electronic component 410 and the electronic component 450 can separate the wiring layer 220 and the wiring layer 320 from each other, and it is possible to reduce propagation of electromagnetic field noise from a power supply wiring pattern 311 of the wiring layer 320 to a power supply wiring pattern 211 of the wiring layer 220. Further, by utilizing the electronic components 410 and 450 which are surface-mounted components, the wiring board 200 and the wiring board 300 can be connected at low cost.

As illustrated in FIG. 10, the electronic components 410 and 450 are arranged side by side in the X direction such that the terminal 411 of the electronic component 410 and the terminal 452 of the electronic component 450 face each other in the X direction. The terminal 411 of the electronic component 410 connected to the analog power supply wiring 22 is closer to the terminal 452 connected to the ground wiring among the terminals 451 and 452 of the electronic component 450. With such a configuration, the terminal 452 connected to the ground wiring is disposed between the terminal 451 connected to the digital power supply wiring 32 and the terminal 411 connected to the analog power supply wiring 22, so that it is possible to reduce propagation of electromagnetic field noise from the terminal 451 to the terminal 411.

Although the arrangement of the electronic component 410 has been described, it is possible to reduce propagation of electromagnetic field noise by arranging the electronic component 450 in the same manner.

As described above, according to the third embodiment, also in a configuration in which the wiring boards 200 and 300 are connected via the electronic components 410 and 450, electromagnetic field noise propagating from the power supply wiring pattern 311 to the power supply wiring pattern 211 can be reduced, so that malfunction of the semiconductor element 10 and occurrence of image disturbance due to, for example, a semiconductor element 10 serving as an imaging element can be reduced similarly to the first embodiment.

### Fourth Embodiment

An imaging module according to a fourth embodiment will be described. Hereinafter, elements denoted by reference signs common to the first to third embodiments will have basically the same configurations and actions as those described in the first to third embodiments unless otherwise specified, and portions different from those of the first to third embodiments will be mainly described.

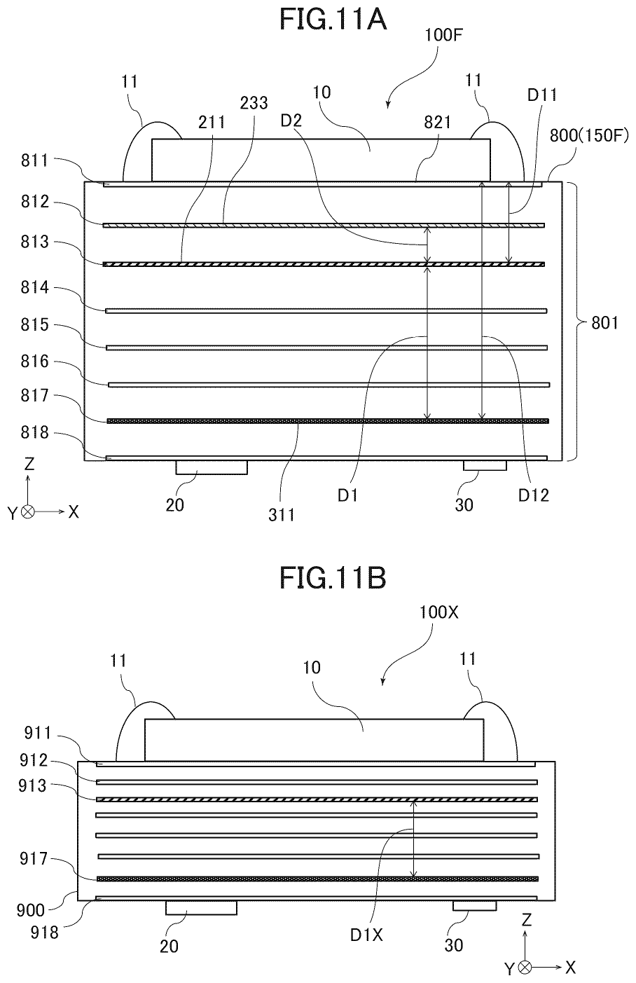

FIG. 11A is a schematic cross-sectional view of an imaging module 100F according to the fourth embodiment. FIG. 11B is a schematic cross-sectional view of an imaging module 100X of a first comparative example. The imaging module 100F of the fourth embodiment illustrated in FIG. 11A is different from the imaging module 100 of the first embodiment in that the connection member 400 is not provided, and the imaging module 100F includes one wiring board 800 instead of the wiring board 200 and the wiring board 300. That is, a wiring unit 150F of the imaging module 100F is the wiring board 800. The wiring board 800 is a printed wiring board, for example, a rigid board. The wiring board 800 is a multilayer board including a plurality of wiring layers 801. The plurality of wiring layers 801 have the same configuration as that of the plurality of wiring layers 201 and the plurality of wiring layers 301 of the first embodiment. A semiconductor element 10 is mounted on a mounting surface 821 of the wiring board 800. The wiring board 800 includes eight layers 811 to 818. Each of the eight layers 811 to 818 is a wiring layer. The eight layers 811 to 818 are arranged in this order from the mounting surface 821 toward the −Z-axis direction.

Therefore, in the imaging module 100F of the fourth embodiment, a power supply wiring pattern 211 and a power supply wiring pattern 311 are provided in the same wiring board 800. In the fourth embodiment, a distance D1 between the third layer 813 in which the power supply wiring pattern 211 (FIG. 2B) is disposed and the seventh layer 817 in which the power supply wiring pattern 311 (FIG. 2C) is disposed in the Z direction is 500 μm or more in some embodiments, and is 900 μm or more in a more specific embodiment. The third layer 813 corresponds to the wiring layer 220 of the first embodiment, and the seventh layer 817 corresponds to the wiring layer 320 of the first embodiment. The third layer 813 is an example of a first wiring layer, and the seventh layer 817 is an example of a second wiring layer. The configuration of the wiring layer 220 and the configuration of the wiring layer 320 are as described in the first embodiment, and a detailed description of a configuration of the third layer 813 corresponding to the wiring layer 220 and a configuration of the seventh layer 817 corresponding to the wiring layer 330 will be omitted.

The imaging module 100X of the first comparative example illustrated in FIG. 11B includes a wiring board 900 instead of the wiring board 800. The wiring board 900 is an eight-layer board having a thickness of 0.8 mm. It is assumed that a thickness of a semiconductor element 10 is 0.8 mm. A pad 12 to which a wire 11 led out from the semiconductor element 10 is connected is disposed in a first layer 911 on which the semiconductor element 10 is mounted. In addition, wirings such as a signal wiring and a power supply wiring are also provided in the first layer 911. In a second layer 912, a solid ground pattern is provided in order to ensure potential stability of the wiring provided in the first layer 911. The solid ground pattern provided in the second layer 912 is shared as solid ground patterns in a ground wiring 33 and a ground wiring 23. That is, a solid ground pattern 233 provided in the second layer 912 serves as both the ground patterns of the ground wiring 33 and the ground wiring 23. A circuit component 20 and a connector component 30 are provided on the eighth layer 918 of the wiring board 900, the eighth layer 918 being positioned opposite to the first layer 911. Therefore, in order to separate a power supply wiring pattern 211 and a power supply wiring pattern 311 from each other, the power supply wiring pattern 211 is disposed in the third layer 913, and the power supply wiring pattern 311 is disposed in the seventh layer 917. In this case, in the wiring board 900 having a thickness of 0.8 mm, a distance DIX between the third layer 913 in which the power supply wiring pattern 211 is disposed and the seventh layer 917 in which the power supply wiring pattern 311 is disposed is about 450 μm.

In the imaging module 100F of the fourth embodiment illustrated in FIG. 11A, the wiring board 800 is an eight-layer board having a thickness of 1.6 mm. It is assumed that a thickness of the semiconductor element 10 is 0.8 mm. A pad 12 to which a wire 11 led out from the semiconductor element 10 is connected is disposed in the first layer 811 on which the semiconductor element 10 is mounted. In addition, wirings such as a signal wiring and a power supply wiring are also provided in the first layer 811. In a second layer 812, a solid ground pattern 233 is provided in order to ensure potential stability of the wiring provided in the first layer 811. The solid ground pattern 233 provided in the second layer 812 is shared as solid ground patterns in a ground wiring 33 and a ground wiring 23. That is, the solid ground pattern 233 provided in the second layer 812 serves as both the ground patterns of the ground wiring 33 and the ground wiring 23. A circuit component 20 and a connector component 30 are provided on the eighth layer 818 of the wiring board 800, the eighth layer 818 being positioned opposite to the first layer 811. Therefore, in order to separate a power supply wiring pattern 211 and a power supply wiring pattern 311 from each other, the power supply wiring pattern 211 is disposed in the third layer 813, and the power supply wiring pattern 311 is disposed in the seventh layer 817.

In the fourth embodiment, a distance D1 between the third layer 813 in which the power supply wiring pattern 211 is disposed and the seventh layer 817 in which the power supply wiring pattern 311 is disposed in the Z direction is 500 μm or more, which is larger than the distance DIX, and is 900 μm or more in a more specific embodiment.

An effect of setting the distance D1 between the power supply wiring pattern 211 and the power supply wiring pattern 311 to 900 μm, which is twice the distance DIX in the first comparative example, will be described. In a case where a current I flows through a linear conductor having a straight line shape, a magnetic flux density B at a point P separated from the linear conductor by a distance a is expressed by the following Formula (1). μ₀ represents magnetic permeability of vacuum.

$$\begin{matrix}Mathematical Formula 1 & \\ B = \frac{{μ}_{0}}{2 π} \times \frac{I}{a} & ( 1 )\end{matrix}$$

As can be seen from Formula (1), a magnitude of the magnetic flux density B is inversely proportional to the distance a from the linear conductor. Therefore, in the imaging module 100F of the fourth embodiment, a propagation amount of noise reaching the power supply wiring pattern 211 from the power supply wiring pattern 311 is reduced to about ½ times of that in the first comparative example. In an imaging device, since the propagation amount of noise is reduced to ½, sensitivity of the imaging device is improved twice.

As described above, according to the fourth embodiment, by setting the distance D1 between the third layer 813 in which the power supply wiring pattern 211 is disposed and the seventh layer 817 in which the power supply wiring pattern 311 is disposed in the Z direction to 500 μm or more, more specifically, 900 μm or more, electromagnetic field noise propagating from the power supply wiring pattern 311 to the power supply wiring pattern 211 is reduced. As a result, it is possible to reduce malfunction of the semiconductor element 10 and occurrence of image disturbance due to, for example, the semiconductor element 10 serving as an imaging element.

A distance D12 between the mounting surface 821 of the wiring board 800 on which the semiconductor element 10 is mounted and the seventh layer 817 in which the power supply wiring pattern 311 is disposed in the Z direction is longer than a distance D11 between the mounting surface 821 on which the semiconductor element 10 is mounted and the third layer 813 in which the power supply wiring pattern 211 is disposed in the Z direction. That is, the power supply wiring pattern 311 is disposed farther from the semiconductor element 10 than the power supply wiring pattern 211. As described above, the power supply wiring pattern 311 from which noise is radiated can be kept away from the semiconductor element 10.

The fourth layer 814, the fifth layer 815, and the sixth layer 816 are disposed between the third layer 813 and the seventh layer 817. Each of the layers 814, 815, and 816 is an example of a third wiring layer. Since other layers 814, 815, and 816 are disposed between the third layer 813 and the seventh layer 817, the distance between the third layer 813 and the seventh layer 817 can be increased, and thus, the electromagnetic field noise propagating from the power supply wiring pattern 311 to the power supply wiring pattern 211 is effectively reduced, so that the malfunction of the semiconductor element 10 and the occurrence of image disturbance due to, for example, the semiconductor element 10 serving as the imaging element is effectively reduced.

Also in the fourth embodiment, similarly to the first embodiment, the distance D2 is shorter than the distance D1.

At least a part of the power supply wiring pattern 211 can overlap with at least a part of the power supply wiring pattern 311 in the Z direction. Accordingly, the wiring board 800 can be downsized.

In the fourth embodiment, a case where the thickness of the wiring board 800 is 1.6 mm has been described as an example, but the thickness of the wiring board 800 is not limited thereto. As long as the distance D1 between the power supply wiring pattern 211 and the power supply wiring pattern 311 can be set to 900 μm or more, the thickness of the wiring board 800 may be made smaller than 1.6 mm.

In the fourth embodiment, a case where the power supply wiring pattern 211 is disposed in the third layer 813 and the power supply wiring pattern 311 is disposed in the seventh layer 817 has been described as an example, but the present technology is not limited thereto, and the power supply wiring pattern 211 and the power supply wiring pattern 311 may be disposed in different layers. A core layer of an insulating substrate may be disposed between the power supply wiring pattern 211 and the power supply wiring pattern 311.

### Other Modified Examples

Note that the present disclosure is not limited to the embodiments described above, and many modifications can be made within the technical idea of the present disclosure. For example, at least two of the plurality of embodiments and the plurality of modified examples described above may be combined. In addition, the effects described in the present embodiment merely enumerate the most preferable effects that result from the embodiment of the present disclosure, and the effects of the embodiments of the present disclosure are not limited to those described in the present embodiment.

In the above-described embodiments, a case where the power supply wiring pattern 211 and the power supply wiring pattern 311 are disposed in different wiring layers has been described, but the present technology is not limited thereto. For example, the power supply wiring pattern 211 and the power supply wiring pattern 311 may be disposed in the same wiring layer. Here, the distance D1 between the power supply wiring pattern 211 and the power supply wiring pattern 311 is 500 μm or more, more specifically, 900 μm or more. As a result, electromagnetic coupling (capacitive coupling and/or inductive coupling) between the power supply wiring pattern 211 and the power supply wiring pattern 311 is reduced, and electromagnetic field noise propagating from the power supply wiring pattern 311 to the power supply wiring pattern 211 is reduced.

However, from the viewpoint of reducing the area of the wiring board, the power supply wiring pattern 211 and the power supply wiring pattern 311 can be disposed in different wiring layers as described in the above-described embodiments. Further, from the viewpoint of reducing noise propagating from the power supply wiring pattern 211 and the power supply wiring pattern 311 to the semiconductor element 10, the power supply wiring pattern 211 and the power supply wiring pattern 311 do not overlap with the semiconductor element 10 in the Z direction in some embodiments. From the viewpoint of further downsizing the wiring board, at least a part of the power supply wiring pattern 211 can overlap with at least a part of the power supply wiring pattern 311 in the Z direction. As described above, in a configuration in which at least a part of the power supply wiring pattern 211 and at least a part of the power supply wiring pattern 311 overlap with each other in the Z direction, from the viewpoint of reducing the electromagnetic coupling, the power supply wiring pattern 211 and the power supply wiring pattern 311 are disposed in the wiring boards 200 and 300 different from each other in some embodiments, and another wiring layer is disposed between the wiring layer 220 (813) and the wiring layer 320 (817) in a more specific embodiment.

Furthermore, in the above-described embodiments, a case where the analog power supply wiring 22 is the first power wiring, the digital power supply wiring 32 is the second power wiring, the ground wiring 33 is the third power wiring, and the ground wiring 23 is the fourth power wiring has been described as an example, but the present technology is not limited thereto. For example, the analog power supply wiring 22 may be the first power wiring, the ground wiring 33 may be the second power wiring, the digital power supply wiring 32 may be the third power wiring, and the ground wiring 23 may be the fourth power wiring. In addition, for example, the ground wiring 23 may be the first power wiring, the ground wiring 33 may be the second power wiring, the digital power supply wiring 32 may be the third power wiring, and the analog power supply wiring 22 may be the fourth power wiring. In addition, for example, the ground wiring 23 may be the first power wiring, the digital power supply wiring 32 may be the second power wiring, the ground wiring 33 may be the third power wiring, and the analog power supply wiring 22 may be the fourth power wiring. Then, as long as the third power wiring and the fourth power wiring have the same potential, the third power wiring and the fourth power wiring may be implemented by one power wiring.

Furthermore, in the above-described embodiments, a case where the electronic module is applied to the imaging module has been described as an example, but the present technology is not limited thereto, and the electronic module of the present disclosure may be applied to the processing module.

Furthermore, in the above-described embodiments, a case where the electronic module of the present disclosure is applied to the imaging device such as a digital camera has been described, but the present technology is not limited thereto. The electronic module of the present disclosure is also applicable to information equipment such as a smartphone and a personal computer, communication equipment such as a modem and a router, and the like. Alternatively, the electronic module of the present disclosure can be applied to office equipment such as a printer and a copier, medical equipment such as an X-ray imaging device and an endoscope, industrial equipment such as a robot and a semiconductor manufacturing device, transportation equipment such as a vehicle, an airplane, and a ship, and the like.

Furthermore, the contents of disclosure in the present specification include not only contents described in the present specification but also all of the items which are understandable from the present specification and the drawings accompanying the present specification. Moreover, the contents of disclosure in the present specification include a complementary set of concepts described in the present specification. Thus, if, in the present specification, there is a description indicating that, for example, “A is B”, even when a description indicating that “A is not B” is omitted, the present specification can be said to disclose a description indicating that “A is not B”. This is because, in a case where there is a description indicating that “A is B”, taking into consideration a case where “A is not B” is a premise.

As described above, according to the present disclosure, it is possible to provide an advantageous technology for stabilizing the operation of the analog circuit of the semiconductor element.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2024-177314, filed Oct. 9, 2024, which is hereby incorporated by reference herein in its entirety.

What is claimed is:

1. An electronic module comprising:
a semiconductor element including an analog circuit and a digital circuit; and
a wiring unit having a mounting surface on which the semiconductor element is mounted, and including a first power wiring used to supply power to the analog circuit, a second power wiring used to supply power to the digital circuit, and a third power wiring used to supply power to the digital circuit, wherein
the first power wiring includes two or more first power wiring patterns disposed in two or more wiring layers of the wiring unit,
the second power wiring includes two or more second power wiring patterns disposed in two or more wiring layers of the wiring unit,
the wiring unit includes a first wiring layer in which a first wiring pattern having a largest area among the two or more first power wiring patterns is disposed and a second wiring layer in which a second wiring pattern having a largest area among the two or more second power wiring patterns is disposed,
a distance between the first wiring layer and the second wiring layer is 500 μm or more,
at least a first portion of the first wiring pattern overlaps with at least a second portion of the second wiring pattern in a direction perpendicular to the mounting surface, and
the wiring unit includes a third wiring layer disposed between the first portion and the second portion in the direction perpendicular to the mounting surface.

2. An electronic module comprising:
a semiconductor element including an analog circuit and a digital circuit; and
a wiring unit having a mounting surface on which the semiconductor element is mounted, and including a first power wiring used to supply power to the analog circuit and a second power wiring used to supply power to the digital circuit, wherein
the first power wiring includes two or more first power wiring patterns disposed in two or more wiring layers of the wiring unit,
the second power wiring includes two or more second power wiring patterns disposed in two or more wiring layers of the wiring unit, and
a distance between a first wiring pattern having a largest area among the two or more first power wiring patterns and a second wiring pattern having a largest area among the two or more second power wiring patterns is 900 μm or more.

3. An electronic module comprising:
a semiconductor element including an analog circuit and a digital circuit; and
a wiring unit having a mounting surface on which the semiconductor element is mounted, and including a first power wiring used to supply power to the analog circuit and a second power wiring used to supply power to the digital circuit, wherein
the first power wiring includes two or more first power wiring patterns disposed in two or more wiring layers of the wiring unit,
the second power wiring includes two or more second power wiring patterns disposed in two or more wiring layers of the wiring unit,
the wiring unit includes a first wiring board and a second wiring board stacked on each other,
a first wiring pattern having a largest area among the two or more first power wiring patterns is provided in the first wiring board, and
a second wiring pattern having a largest area among the two or more second power wiring patterns is provided in the second wiring board.

4. The electronic module according to claim 3, wherein a distance between a first wiring layer in which the first wiring pattern is disposed and a second wiring layer in which the second wiring pattern is disposed is 500 μm or more.

5. The electronic module according to claim 2, wherein the wiring unit includes a third wiring layer disposed between a first wiring layer in which the first wiring pattern is disposed and a second wiring layer in which the second wiring pattern is disposed.

6. The electronic module according to claim 2, wherein at least a part of the first wiring pattern overlaps with at least a part of the second wiring pattern in a direction perpendicular to the mounting surface.

7. The electronic module according to claim 1, wherein a distance between the mounting surface and the second wiring pattern is longer than a distance between the mounting surface and the first wiring pattern.

8. The electronic module according to claim 1, wherein a potential of the first power wiring is equal to or higher than a potential of the second power wiring.

9. The electronic module according to claim 3, wherein
a gap is formed between the first wiring board and the second wiring board, and/or
the electronic module further comprises a shield member disposed between the first wiring board and the second wiring board.

10. The electronic module according to claim 3, wherein the wiring unit includes one or more connection members disposed between the first wiring board and the second wiring board and connecting between the first wiring board and the second wiring board.

11. The electronic module according to claim 10, wherein
a part of the first power wiring is disposed in a first connection member among the one or more connection members, and
a part of the second power wiring is disposed in a second connection member among the one or more connection members.

12. The electronic module according to claim 11, wherein
a first side surface of the first connection member and a second side surface of the second connection member face each other, and
the electronic module further comprises a shield member disposed on at least one of the first side surface of the first connection member and the second side surface of the second connection member.

13. The electronic module according to claim 11, wherein
a first side surface of the first connection member and a second side surface of the second connection member face each other,
the first connection member includes a first ground line, and
the first ground line is disposed between the part of the first power wiring and the first side surface of the first connection member, and/or
the first side surface of the first connection member and the second side surface of the second connection member face each other,
the second connection member includes a second ground line, and
the second ground line is disposed between the part of the second power wiring and the second side surface of the second connection member.

14. The electronic module according to claim 1, wherein
each of the two or more first power wiring patterns includes one or more wirings disposed in a corresponding wiring layer among the two or more wiring layers in which the two or more first power wiring patterns are disposed, and/or
each of the two or more second power wiring patterns includes one or more wirings disposed in a corresponding wiring layer among the two or more wiring layers in which the two or more second power wiring patterns are disposed.

15. The electronic module according to claim 3, further comprising one or more electronic components disposed between the first wiring board and the second wiring board.

16. The electronic module according to claim 15, wherein the first wiring board and the second wiring board are connected via the one or more electronic components.

17. The electronic module according to claim 15, wherein
the one or more electronic components include a first electronic component and a second electronic component,
the first electronic component includes a first terminal and a second terminal,
the second electronic component includes a third terminal and a fourth terminal,
the first power wiring is connected to the first terminal of the first electronic component, and
the second power wiring is connected to the third terminal of the second electronic component.

18. The electronic module according to claim 17, wherein the first terminal of the first electronic component is closer to the fourth terminal among the third terminal and the fourth terminal of the second electronic component.

19. The electronic module according to claim 1, wherein
the wiring unit includes a plurality of pads disposed on the mounting surface and electrically connected to the semiconductor element, and
the plurality of pads are arranged at intervals along an outer periphery of a region where the semiconductor element is mounted on the mounting surface.

20. The electronic module according to claim 19, wherein
the first power wiring includes at least two pads among the plurality of pads, and
the first wiring pattern overlaps with the at least two pads of the first power wiring in the direction perpendicular to the mounting surface, and/or
the second power wiring includes at least two pads among the plurality of pads, and
the second wiring pattern overlaps with the at least two pads of the second power wiring in the direction perpendicular to the mounting surface.

21. The electronic module according to claim 1, wherein
at least a part of the first wiring pattern does not overlap with the semiconductor element in the direction perpendicular to the mounting surface, and/or
at least a part of the second wiring pattern does not overlap with the semiconductor element in the direction perpendicular to the mounting surface.

22. The electronic module according to claim 1, wherein
the first wiring pattern is formed in a C shape, and/or
the second wiring pattern is formed in a C shape.

23. The electronic module according to claim 1, further comprising a plurality of wires bonded to the semiconductor element and the mounting surface.

24. The electronic module according to claim 1, further comprising a plurality of wires bonded to the semiconductor element, wherein the semiconductor element is disposed between at least two wires among the plurality of wires, and the at least two wires electrically connect the first power wiring and the semiconductor element.

25. The electronic module according to claim 3, wherein the first wiring board is disposed between the semiconductor element and the second wiring board.

26. The electronic module according to claim 1, wherein
the wiring unit includes a wiring board on which the semiconductor element is mounted,
the first wiring pattern and the second wiring pattern are provided in the wiring board, and
a potential of the first power wiring is different from a potential of the third power wiring.

27. The electronic module according to claim 1, wherein
the wiring unit includes a fourth power wiring used to supply power to the analog circuit,
the fourth power wiring includes two or more fourth power wiring patterns disposed in two or more wiring layers of the wiring unit, and
a distance between the first wiring pattern and a fourth wiring pattern having a largest area among the two or more fourth power wiring patterns is shorter than a distance between the first wiring pattern and the second wiring pattern.

28. The electronic module according to claim 1, wherein the semiconductor element is a stacked-type semiconductor element in which a first chip including the analog circuit and a second chip including the digital circuit are stacked on each other.

29. The electronic module according to claim 1, wherein the semiconductor element is an imaging element.

30. Electronic equipment comprising:
an exterior housing;
a first electronic module which is the electronic module according to claim 1 and is disposed inside the exterior housing;
a flexible wiring component connected to the wiring unit; and
a second electronic module electrically connected to the first electronic module via the wiring component.
